(19) United States
(12) Patent Application Publication
(10) Pub. No.: US 2010/0254546 A1
(43) Pub. Date: Oct. 7, 2010

(54) SIGNAL PROCESSING DEVICE, SIGNAL PROCESSING METHOD, AND COMPUTER PROGRAM

(75) Inventor: Okifumi HOSOMI, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: SONY CORPORATION, Tokyo (JP)

(21) Appl. No.: 12/700,773

(22) Filed: Feb. 5, 2010

(30) Foreign Application Priority Data
Apr. 3, 2009 (JP) 2009-090585

(51) Int. Cl. H03G 7/00; H03G 3/00

(52) U.S. Cl. 381/106; 381/104

(57) ABSTRACT

A signal processing device includes: a frequency conversion processing unit that sets, as a processing target signal, a section in which a peak signal level exceeds a first threshold in an input sound signal and applies frequency conversion processing to the processing target signal to acquire power levels in respective plural bands; and an amplitude compressing unit that executes, when a power level exceeding a second threshold is present among the power levels in the respective plural bands acquired by the frequency conversion processing unit, amplitude compression processing for compressing a signal level of the processing target signal at a compression ratio at which the peak signal level of the processing target signal falls within the first threshold and, otherwise, prohibits the execution of the amplitude compression processing.

### BACKGROUND OF THE INVENTION

1. Field of the Invention

The present invention relates to a signal processing device, a signal processing method, and a computer program, and, more particularly to a signal processing device, a signal processing method, and a computer program adapted to be capable of recording and reproducing sound more faithful to original sound.

2. Description of the Related Art

There is a sound recording device that records environmental sound input from a microphone. An amplitude range of the environmental sound input to the sound recording device is about 20 dBSPL to 130 dBSPL. When the sound recording device directly records such amplitude information (a sound signal of the environmental sound), a circuit having a dynamic range applicable to the amplitude range needs to be mounted on the sound recording device. However, cost for such a circuit is extremely high. Therefore, usually, a method of limiting the amplitude of an input sound signal using an AGC (Auto Gain Control) circuit (hereinafter referred to as amplitude limiting method) is adopted. There is a method of interpolating, when a waveform of the input sound signal is distorted because the waveform reaches the dynamic range of the circuit, a waveform of a distorted portion (hereinafter referred to as clip portion) (hereinafter referred to as waveform interpolation method) (see, for example, JP-A-60-202576 (Patent Document 1) and JP-A-53-30257 (Patent Document 2)).

### SUMMARY OF THE INVENTION

The amplitude limiting method in the past is explained below. AGC circuits to which the amplitude limiting method in the past is applied (hereinafter simply referred to as AGC circuits in the past) are roughly classified into a circuit of a feedback format (hereinafter referred to as FB format) and a circuit of a feed-forward format (hereinafter referred to as FF format).

### [An Example of the AGC Circuit of the FB Format in the Past]

FIG. 1 is a diagram of an example of the AGC circuit of the FB format in the past. An AGC circuit 10 of the FB format in the past of the example shown in FIG. 1 includes an amplifier 11 and a detector circuit 12. The amplifier 11 amplifies an input sound signal with predetermined gain and outputs the input sound signal. The sound signal amplified by the amplifier 11 is fed back to the detector circuit 12. The detector circuit 12 detects the amplitude of the amplified sound signal and changes the gain of the amplifier 11 on the basis of a result of the detection.

### [An Example of the AGC Circuit of the FF Format in the Past]

FIG. 2 is a diagram of an example of the AGC circuit of the FF format in the past. An AGC circuit 20 of the FF format in the past of the example shown in FIG. 2 includes a delay circuit 21, a detector circuit 22, and an amplifier 23. The delay circuit 21 delays an input sound signal by a predetermined time and supplies the input sound signal to the amplifier 23. The detector circuit 22 detects the amplitude of the input sound signal and changes the gain of the amplifier 23 on the basis of a result of the detection. The amplifier 23 amplifies the sound signal, which is delayed and output by the delay circuit 21, with the gain changed by the detector circuit 22 and outputs the sound signal.

Both the AGC circuits of the FB format and the FF format in the past can lower, when an amplitude value of the input sound signal exceeds a threshold, the gain of the amplifier 11 or 23 to hold down an amplitude value of an output sound signal. However, in the AGC circuit 10 of the FB format in the past, the input sound signal is amplified with the gain before the change for a while after the amplitude value of the input sound signal exceeds the threshold. Therefore, until the gain is changed after the amplitude value of the input sound signal exceeds the threshold, the amplitude value of the output sound signal exceeds the threshold. On the other hand, in the AGC circuit 20 of the FF format in the past, the input sound signal is amplified with the gain after the change immediately after the amplitude value of the input sound signal exceeds the threshold. Therefore, the amplitude value of the output sound signal is limited to fall within the threshold while the amplitude of the input sound signal exceeds the threshold. Therefore, waveform responsiveness is improved in the AGC circuit 20 of the FF format in the past compared with the AGC circuit 10 of the FB format in the past.

### [An Example of the Waveform Responsiveness of the AGC Circuits]of the FB Format and the FF Format in the Past]

FIG. 3 is a diagram of an example of the AGC circuits of the FB format and the FF format in the past.

A of FIG. 3 is a diagram of an example of an envelope of an input sound signal. B of FIG. 3 is a diagram of an example of an envelope of an output sound signal of the AGC circuit 10 of the FB format in the past. C of FIG. 3 is a diagram of an example of an envelope of an output sound signal of the AGC circuit 20 of the FF format in the past.

In the example shown in A of FIG. 3, an amplitude value of the input sound signal exceeds a threshold th in a period from time TA to time TB. In this period, a waveform of the input sound signal reaches a dynamic range d.

As shown in B of FIG. 3, in the AGC circuit 10 of the FB format in the past, time TC when an amplitude value of the output sound signal is held down to fall within the threshold th delays with respect to the time TA when the amplitude value of the input sound signal exceeds the threshold th. Consequently, in a period from the time TA to the time TC, the amplitude value of the output sound signal exceeds the threshold th and an waveform of the output sound signal reaches the dynamic range d.

On the other hand, as shown in C of FIG. 3, in the AGC circuit 20 of the FF format in the past, an amplitude value of the output sound signal is held down to fall within the threshold th in a period from time TA′ to time TB′. In this way, it is seen that the waveform responsiveness is improved in the AGC circuit 20 of the FF format in the past compared with the AGC circuit 10 of the FB format in the past. Each of the time TA′ and TB′ in the example shown in C of FIG. 3 is time after the elapses of a predetermined delay time set in the delay circuit 21 from each of the time TA and the time TB of the example shown in A of FIG. 3.

However, irrespectively of which of the AGC circuits of the FB format and the FF format in the past is adopted, when a sound signal is output immediately after the amplitude value of the input sound signal falls below the threshold th again after exceeding the threshold th, in some case, unnatural sound is generated.

In the example shown in A of FIG. 3, timing when the amplitude value of the input sound signal falls below the threshold th is the time TB. As shown in B of FIG. 3, in the AGC circuit 10 of the FB format in the past, the amplitude value of the output sound signal substantially falls at the time TB and thereafter gradually rises. As shown in C of FIG. 3, in the AGC circuit 20 of the FF format in the past, the amplitude value of the output sound signal substantially falls at the time TB′ and thereafter gradually rises. Such a phenomenon, i.e., a phenomenon in which the amplitude value substantially falls and thereafter gradually rises is called attack recovery. The attack recovery occurs because a response time from the time when the amplitude value of the input sound signal changes across the threshold th until the gain of the amplifier is changed according to the change in the amplitude value (hereinafter referred to as time of the attack recovery) is long. The time of the attack recovery is set long because other harmful effects occur if the time of the attack recovery is short.

[An Example of a Waveform of the Output Sound Signal with Respect to the Time of the Attack Recovery]

FIG. 4 is a diagram for explaining an example of a waveform of the output sound signal with respect to the time of the attack recovery.

A of FIG. 4 is a diagram of an envelope of the input sound signal. B of FIG. 4 is a diagram of an envelope of the output sound signal obtained when the time of the attack recovery is long. C of FIG. 4 is a diagram of an envelope of the output sound signal obtained when the time of the attack recovery is short.

When the time of the attack recovery is short, the AGC circuit changes the gain of the amplifier immediately when the amplitude value of the input sound signal crosses the threshold th. Therefore, as shown in B of FIG. 4, the amplitude of the output sound signal is uniformalized. As a result, envelope information of the input sound signal is lost. Sound corresponding to such an output sound signal is sound without a change in sound volume that should originally occur. Therefore, in some case, a viewer feels a sense of discomfort in audibility. This is a harmful effect that occurs when the time of attack recovery is short.

On the other hand, when the time of the attack recovery is long, the gain of the amplifier is not immediately changed even if the amplitude value of the input sound signal crosses the threshold th. Therefore, as shown in C of FIG. 4, envelope information of the input sound signal remains. Therefore, it is possible to form a shape of the output sound signal to be close to a shape of the input sound signal. However, if the time of the attack recovery is set too long, the amplitude value of the input sound signal is smaller than the threshold th and the amplitude value of the output sound signal remains small. As a result, the volume of the sound corresponding to the output sound signal is kept turned down.

Therefore, as the time of the attack recovery, optimum time is pursued and set. This is a cause of complicated design of the AGC circuit in the past.

In the AGC circuit in the past, it is necessary to detect an amplitude value of the input sound signal. The detection of an amplitude value is also referred to as level detection. As a method for level detection in the past, a method of simply detecting an amplitude value of the input sound signal (hereinafter referred to as peak detection method) and a method of integrating an effective value of the input sound signal in a time direction and detecting an amplitude value (hereinafter referred to as integrated detection method) are well known. When the peak detection method is applied, the AGC circuit in the past also reacts to an input sound signal, an amplitude value of which instantaneously exceeds the threshold. The amplitude of the input sound signal is compressed. Therefore, for example, if a large number of noise components are included in the input sound signal, a phenomenon in which the amplitude of the output sound signal is excessively held down occurs. On the other hand, when the integrated detection method is applied, this phenomenon does not occur. However, it is difficult for the AGC circuit in the past to compress the amplitude with respect to the input sound signal, the amplitude value of which instantaneously exceeds the threshold. Therefore, in some case, the AGC circuit in the past does not compress the amplitude of a high-frequency input sound signal even if an amplitude value of the input sound signal exceeds the threshold. Therefore, it is likely that a waveform of the output sound signal reaches the dynamic range and a waveform is distorted. As explained above, in the AGC circuit in the past, there is room for improvement in the level detecting method.

Further, the AGC circuit in the past is often realized by an analog circuit of the FB format for which circuit design is easy. Therefore, in the AGC circuit in the past, a circuit area is relatively large and cost rises.

The amplitude limiting method performed by using the AGC circuit in the past is explained above. The methods disclosed in Patent Documents 1 and 2 are explained below as the waveform interpolation method in the past.

In the methods disclosed in Patent Documents 1 and 2, when a clip portion is included in a sound signal after A/D conversion by an A/D (analog to digital) converter, waveform interpolation explained below is performed. Specifically, in the method disclosed in Patent Document 1, waveform interpolation for generating a new waveform from waveforms before and after the clip portion in the sound signal after the A/D conversion and replacing a waveform of the clip portion with the new waveform is performed. In the method disclosed in Patent Document 2, waveform interpolation for replacing the waveform of the clip portion in the sound signal subjected to the A/D conversion with a waveform of a known sine wave or a triangular wave is performed.

However, in both the methods disclosed in Patent Documents 1 and 2, it is necessary to design a dynamic range of the circuit to be wider than a dynamic range of the A/D converter. Therefore, in the methods disclosed in Patent Documents 1 and 2, a circuit size increases and cost increases. Further, in the method disclosed in Patent Document 2, it is highly likely that the replacing waveform (the waveform of the sine wave or the triangular wave) is totally unrelated to the original waveform. Therefore, the replacing waveform and the original waveform are unnaturally connected and distortion of the output sound signal increases. As a result, a person who listens to sound corresponding to the output sound signal feels a sense of discomfort in audibility.

The above explanation is summarized as follows. In the amplitude limiting method in the past, in some case, the envelope information of the input sound signal does not sufficiently remain when the amplitude of the input sound signal is limited. In the waveform interpolation method in the past, the waveform of the clip portion in the waveform of the input sound signal can be replaced. However, the replacing waveform is not always appropriate and it is difficult to limit the amplitude value. As a result, it is highly likely that sound after the waveform interpolation is performed is different from original sound.

Therefore, it is desirable to make it possible to record and reproduce sound more faithful to original sound.

According to an embodiment of the present invention, there is provided a signal processing device including: a frequency conversion processing unit that sets, as a processing target signal, a section in which a peak signal level exceeds a first threshold in an input sound signal and applies frequency conversion processing to the processing target signal to acquire power levels in respective plural bands; and an amplitude compressing unit that executes, when a power level exceeding a second threshold is present among the power levels in the respective plural bands acquired by the frequency conversion processing unit, amplitude compression processing for compressing a signal level of the processing target signal at a compression ratio at which the peak signal level of the processing target signal falls within the first threshold and, otherwise, prohibits the execution of the amplitude compression processing.

It is preferable that the signal processing device further includes: a clip detecting unit that detects, out of the input sound signal, a clip portion, a waveform of which is distorted by a dynamic range of a circuit; and a waveform interpolating unit that interpolates, in the processing target signal subjected to the amplitude compression processing by the amplitude compressing unit, a waveform of a sound signal in which the clip portion is detected by the clip detecting unit and changes the waveform to a waveform in which the peak signal level is the first threshold.

It is preferable that the signal processing device further includes a zero-cross detecting unit that detects, concerning the input sound signal, a position of a point where a signal level crosses a bias as a zero-cross, and a processing unit of the clip detecting unit and a unit of the processing target signal are a signal between a pair of the zero-crosses detected by the zero-cross detecting unit.

It is preferable that the amplitude compressing unit applies, when the clip portion detected by the clip detecting unit is included in the processing target signal, the amplitude compression processing to the processing target signal at the compression ratio corresponding to time length of the clip portion.

It is preferable that the amplitude compressing unit applies, when the clip portion detected by the clip detecting unit is not included in the processing target signal, the amplitude compression processing to the processing target signal at the compression ratio at which the peak signal level is the first threshold.

It is preferable that the second threshold has an independent value for each of the plural bands.

It is preferable that the signal processing device further includes a filter unit that applies filtering adjusted to a human audibility characteristic to the power levels in the respective plural bands acquired by the frequency conversion processing unit, and the amplitude compressing unit distinguishes the execution and the prohibition of the amplitude compression processing using the power levels in the respective plural bands subjected to the filtering by the filtering unit.

According to another embodiment of the present invention, there are provided a signal processing method and a computer program corresponding to the signal processing device according to the embodiment explained above.

According to the embodiments of the present invention, a section in which a peak signal level exceeds a first threshold in an input sound signal is set as a processing target signal and frequency conversion processing is applied to the processing target signal to acquire power levels in respective plural bands. When a power level exceeding a second threshold is present among the acquired power levels in the respective plural bands, amplitude compression processing for compressing a signal level of the processing target signal is executed at a compression ratio at which the peak signal level of the processing target signal falls within the first threshold. Otherwise, the execution of the amplitude compression processing is prohibited.

According to the embodiments, it is possible to record and reproduce sound more faithful to original sound.

### BRIEF DESCRIPTION OF THE DRAWINGS

FIG. 1 is a diagram of an example of an AGC circuit of an FB format in the past;

FIG. 2 is a diagram of an example of an AGC circuit of an FF format in the past;

FIG. 3 is a diagram for explaining the AGC circuits shown in FIGS. 1 and 2;

FIG. 4 is a diagram for explaining the AGC circuits shown in FIGS. 1 and 2;

FIG. 5 is a diagram of a configuration example of a sound recording device according to a first embodiment of the present invention;

FIG. 6 is a diagram for explaining a waveform processing circuit shown in FIG. 5;

FIG. 7 is a diagram for explaining the waveform processing circuit shown in FIG. 5;

FIG. 8 is a diagram for explaining the waveform processing circuit shown in FIG. 5;

FIG. 9 is a diagram for explaining the waveform processing circuit shown in FIG. 5;

FIG. 10 is a diagram for explaining the waveform processing circuit shown in FIG. 5;

FIG. 11 is a diagram for explaining the waveform processing circuit shown in FIG. 5;

FIG. 12 is a diagram for explaining the waveform processing circuit shown in FIG. 5;

FIG. 13 is a diagram for explaining the waveform processing circuit shown in FIG. 5;

FIG. 14 is a diagram for explaining the waveform processing circuit shown in FIG. 5;

FIG. 15 is a diagram for explaining the waveform processing circuit shown in FIG. 5;

FIG. 16 is a diagram for explaining the waveform processing circuit shown in FIG. 5;

FIG. 17 is a diagram for explaining the waveform processing circuit shown in FIG. 5;

FIG. 18 is a diagram for explaining the waveform processing circuit shown in FIG. 5;

FIG. 19 is a diagram for explaining the waveform processing circuit shown in FIG. 5;

FIG. 20 is a diagram for explaining the waveform processing circuit shown in FIG. 5;

FIG. 21 is a diagram of a configuration example of a sound reproducing device according to a second embodiment of the present invention;

FIG. 22 is a diagram of a configuration example of a sound recording device according to a third embodiment of the present invention;

FIG. 23 is diagram for explaining a waveform processing circuit shown in FIG. 22;

FIG. 24 is a diagram for explaining the waveform processing circuit shown in FIG. 22; and

FIG. 25 is a diagram of a configuration example of hardware of a computer according to another embodiment of the present invention.

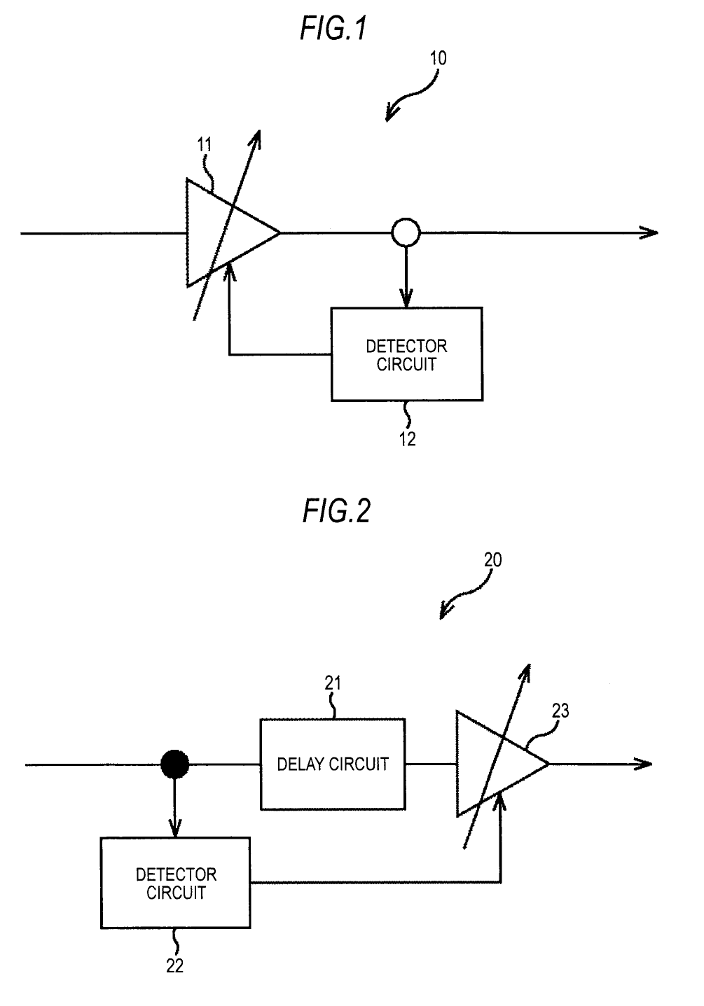

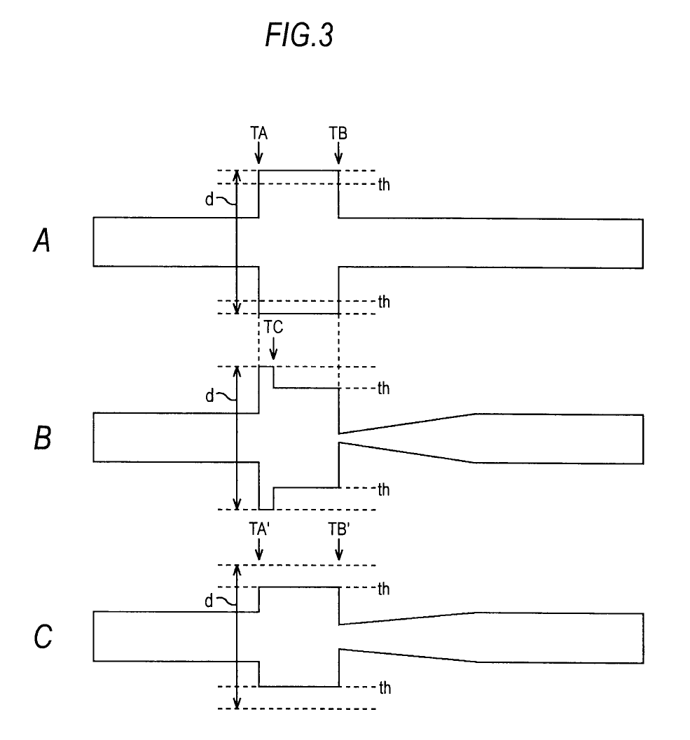

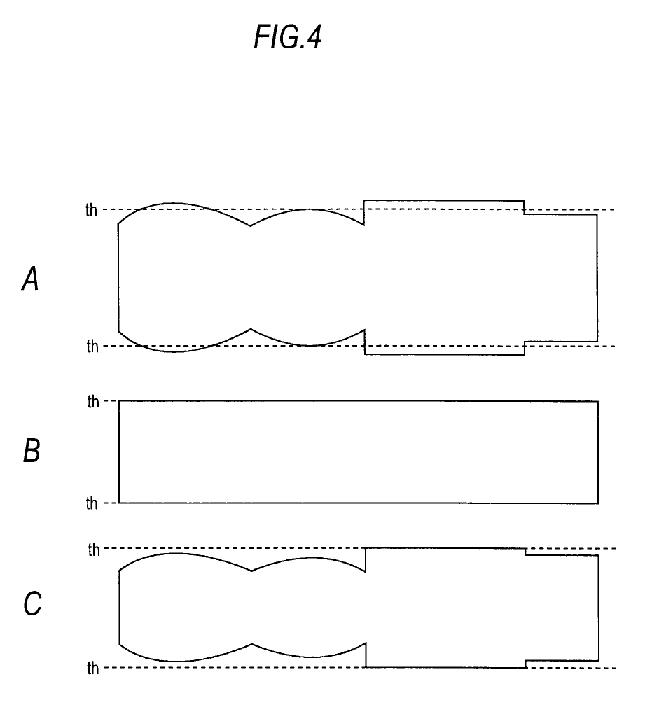

### DETAILED DESCRIPTION OF THE INVENTION

Three embodiments (hereinafter respectively referred to as first to third embodiments) are explained as embodiments of the present invention with reference to the accompanying drawings. Therefore, the explanation is made in the following order:
1. a first embodiment (an example in which the present invention is applied to a sound recording device);
2. a second embodiment (an example in which the present invention is applied to a sound reproducing device); and
3. a third embodiment (an example in which the present invention is applied to a sound recording device).

### 1. First Embodiment

### [A Configuration Example of a Sound Recording Device According to a First Embodiment

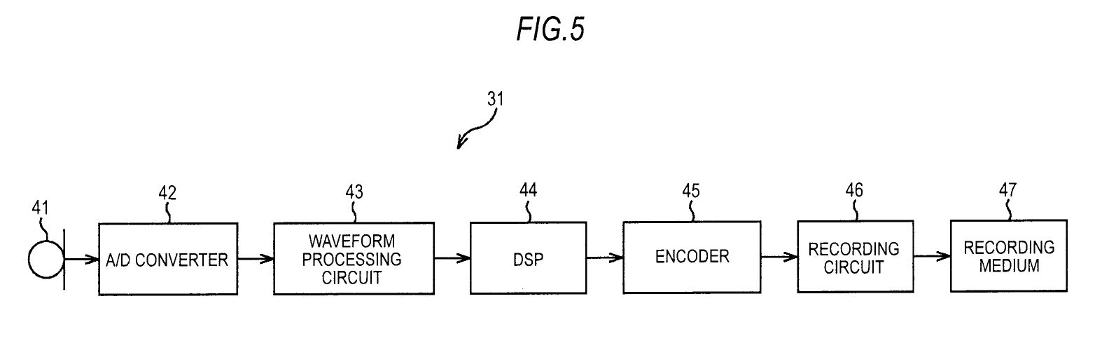

FIG. 5 is a block diagram of a configuration example of a sound recording device as a signal processing device according to a first embodiment of the present invention.

A sound recording device 31 of the example shown in FIG. 5 is configured as, for example, a sound recording section of a video camera. The sound recording device 31 receives the input of sound on the outside as a sound signal via a microphone 41 and applies predetermined processing to the sound. The sound recording device 31 records a sound signal obtained as a result of the processing in a recording medium, for example, a recording medium 47 inserted in the sound recording device 31.

The sound recording device 31 includes the microphone 41, an A/D converter 42, a waveform processing circuit 43, a DSP (Digital Signal Processor) 44, an encoder 45, and a recording circuit 46.

The microphone 41 converts the sound on the outside into an analog sound signal and supplies the analog sound signal to the A/D converter 42. The A/D converter 42 applies A/D conversion to the analog sound signal and then supplies a digital sound signal to the waveform processing circuit 43. The waveform processing circuit 43 applies waveform processing such as amplitude compression processing to the digital sound signal and then supplies the sound signal to the DSP 44. The DSP 44 applies predetermined signal processing to the sound signal from the waveform processing circuit 43 and then supplies the sound signal to the encoder 45. The encoder 45 applies modulation processing to the sound signal from the DSP 44 and then supplies the sound signal to the recording circuit 46. The recording circuit 46 records the modulated sound signal in, for example, the recording medium 47.

The waveform processing circuit 43 of the sound recording device 31 can limit amplitude according to the abilities of the DSP 44 and the encoder 45 while keeping an original waveform as much as possible as explained later. Therefore, the sound recording device 31 is adapted to be capable of recording sound more faithful to original sound in a range of the abilities of the circuits provided in the sound recording device 31.

### [Explanation of a Basic Amplitude Limiting Method]

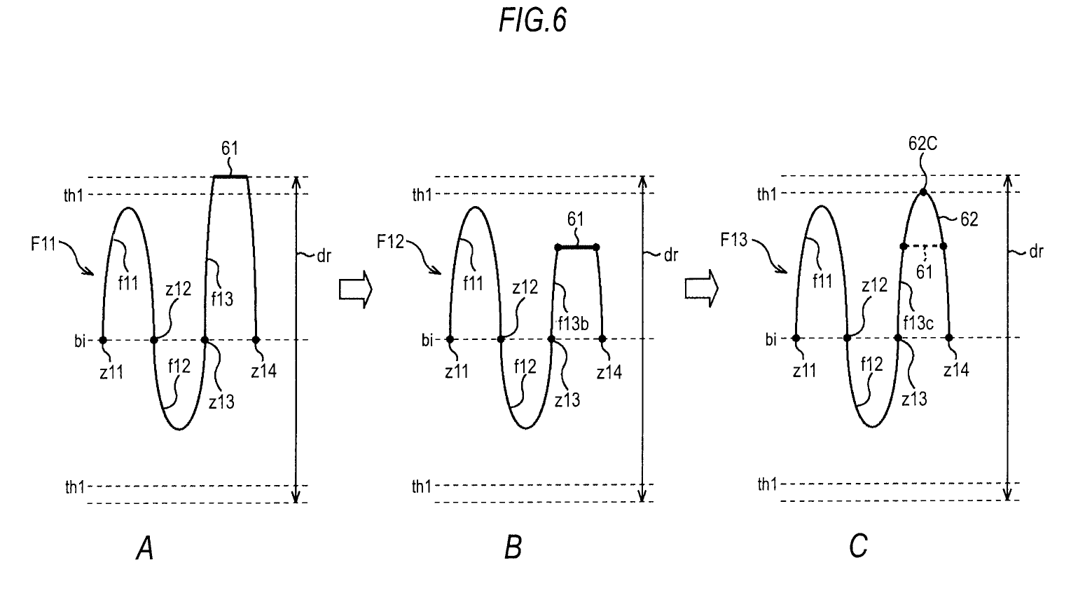

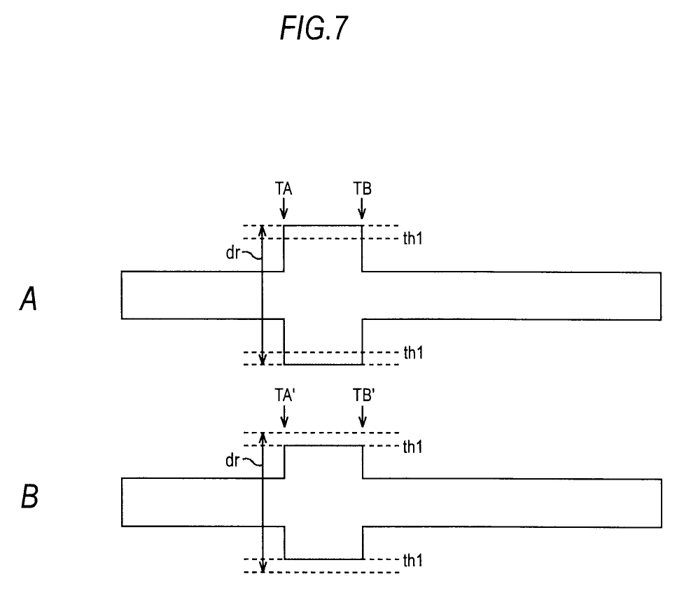

In order to facilitate understanding of the present invention and clarify the background of the present invention, an overview of a basic method among amplitude limiting methods according to this embodiment (hereinafter referred to as basic amplitude limiting method) is explained below with reference to FIGS. 6 and 7.

It is assumed that an operation entity is the waveform processing circuit 43 shown in FIG. 5. In other words, it is assumed that the basic amplitude limiting method is applied to the waveform processing circuit 43 shown in FIG. 5. As shown in FIG. 5, the waveform processing circuit 43 treats a digital sound signal. However, naturally, the waveform processing circuit 43 can also treat an analog sound signal. In this case, for example, an analog sound signal from the microphone 41 is supplied to the waveform processing circuit 43 without the intervention of the A/D converter 42. Further, for example, a circuit having a function of processing and recording an analog sound signal is adopted as a circuit at a post-stage of the waveform processing circuit 43.

FIG. 6 is a diagram for explaining processing by the waveform processing circuit 43 to which the basic amplitude limiting method is applied.

A of FIG. 6 is a diagram of an example of an input sound signal. B of FIG. 6 is a diagram of an example of a sound signal obtained by applying amplitude compression processing to the input sound signal of the example shown in A of FIG. 6. C of FIG. 6 is a diagram of an example of a sound signal obtained by applying waveform interpolation processing to the sound signal of the example shown in B of FIG. 6, i.e., an output sound signal.

In A to C of FIG. 6, a dynamic range dr means a dynamic range of the A/D converter 42. Specifically, when an analog sound signal exceeding the dynamic range dr is input to the A/D converter 42, a portion of a digital sound signal corresponding to an exceeding portion of the analog sound signal is a clip portion. The dynamic range dr and a dynamic range of the waveform processing circuit 43 and the signal processing circuits following the waveform processing circuit 43 explained later are treated as independent from each other.

The waveform processing circuit 43 detects a zero-cross of the input sound signal in pre-processing and divides the input sound signal at the zero-cross. The zero-cross means that a signal level of the input sound signal crosses a reference level (hereinafter referred to as bias) or a position of a point where the signal level crosses the bias in a waveform of the input sound signal. The pre-processing is explained more in detail with reference to A of FIG. 6.

For example, the waveform processing circuit 43 sequentially acquires a signal level of an input sound signal F11 from the left to the right in A of FIG. 6 and determines whether the signal level crosses a bias bi. The waveform processing circuit 43 detects, as a zero-cross, a position of a point where the signal point is determined as crossing the bias bi in a waveform of the input sound signal F11. For example, in the example shown in A of FIG. 6, points z11 to z14 are respectively detected as zero-crosses. The waveform processing circuit 43 divides the input sound signal F11 at the zero-crosses. Respective divided plural sound signals are hereinafter referred to as divided signals. In the example shown in A of FIG. 6, the input sound signal F11 is divided at the zero-crosses z11 to z14 and respective divided plural sound signals f11 to f13 are divided signals.

After ending such pre-processing, the waveform processing circuit 43 executes, for example, processing explained below for each of the plural divided signals. The waveform processing circuit 43 detects signal levels at respective points forming the divided signal (performs peak detection) and determines whether a peak signal level in the divided signal exceeds a first threshold.

As the peak signal level, an amplitude value obtained when the divided signal continues one period may be adopted. However, in this embodiment, for simplification of the explanation, it is assumed that an absolute value of a signal level from a bias is adopted. Therefore, it is assumed that the first threshold is also represented by the absolute value of the signal level from the bias. It is assumed that the dynamic range is also appropriately represented by absolute values of two signal levels equally divided by the bias.

The first threshold is described as “first threshold” to distinguish the first threshold from a second threshold explained later. As the first threshold, for example, an arbitrary value can be adopted depending on a signal processing circuit at a post-stage such as the DSP 44 or the encoder 45. Specifically, for example, a value corresponding to a dynamic range of the signal processing at the post-stage can be adopted as the first threshold.

The waveform processing circuit 43 determines whether a portion that continuously reaches a signal level of the dynamic range dr is present in the divided signal. In this way, the waveform processing circuit 43 determines whether a clip portion is included in a waveform of the divides signal.

The waveform processing circuit 43 determines processing for the divided signal on the basis of results of the determination concerning the peak signal level and the determination concerning the clip portion. As the processing, there are amplitude compression processing and waveform interpolation processing. The amplitude compression processing means processing for setting a divided signal satisfying a predetermined condition as a processing target and compressing a signal level of the processing target.

The amplitude compression processing and the waveform interpolation processing are explained blow with reference to A of FIG. 6 to C of FIG. 6.

The waveform processing circuit 43 sets a divided signal having a peak signal level exceeds the first threshold and including a clip portion among the plural divided signals as a processing target and applies the amplitude compressing processing to the divided signal such that the peak signal level is reduced to be smaller than the first threshold.

For example, in the example shown in A of FIG. 6, peak signal levels of the divided signals f11 and f12 do not exceed a first threshold th1. Therefore, as shown in B of FIG. 6, the divided signals f11 and f12 are not set as processing targets and are not subjected to the amplitude compression processing. On the other hand, a peak signal level of the divided signal f13 exceeds the first threshold th1. The divided signal f13 includes a clip portion 61. Therefore, the divided signal f13 is set as a processing target. Therefore, as shown in B of FIG. 6, the amplitude compression processing is applied to the divided signal f13 such that the peak signal level of the divided signal f13 is reduced to be smaller than the first threshold th1. As a result, a divided signal f13b is obtained.

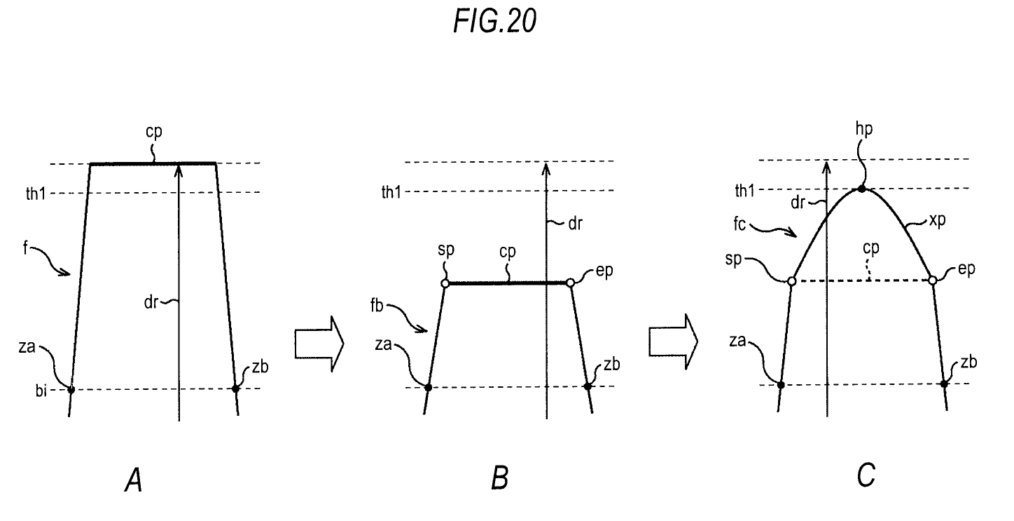

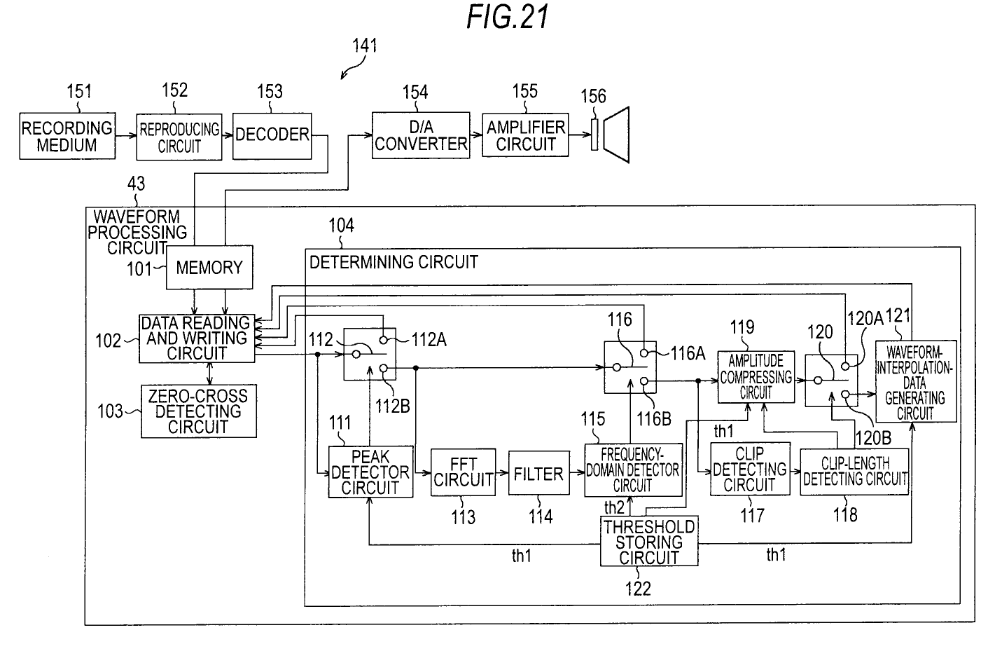

When the amplitude compression processing is applied to the input sound signal F11 of the example shown in A of FIG. 6 in this way, a sound signal F12 of the example shown in B of FIG. 6 is obtained. The waveform processing circuit 43 applies the waveform interpolation processing to the sound signal F12. Specifically, the divided signal f13b after the amplitude compression processing is set as a processing target. As shown in C of FIG. 6, waveform interpolation processing for adding a waveform 62 passing a point 62C having the first threshold th1 as an amplitude value is applied to the clip portion 61 of the processing target. As a result, a divided signal f13c is obtained. A method of the waveform interpolation processing is not specifically limited to the example shown in FIG. 6 as explained later with reference to FIG. 20. As shown in C of FIG. 6, the divided signals f11 and f12 are not set as processing targets and are not subjected to the waveform interpolation processing.

When the waveform interpolation processing is applied to the sound signal F12 of the example shown in B of FIG. 6 in this way, a sound signal F13 of the example shown in C of FIG. 6 is obtained. The sound signal F13 is output from the waveform processing circuit 43 as an output signal.

[An Example of Waveform Responsiveness of the Waveform Processing Circuit to which the Basic Amplitude Limiting Method is Applied]

FIG. 7 is a diagram of an example of waveform responsiveness of the waveform processing circuit 43 to which the basic amplitude limiting method is applied.

A of FIG. 7 is a diagram of an example of an envelope of an input sound signal. B of FIG. 7 is a diagram of an example of an envelope of an output signal.

In the example shown in A of FIG. 7, the amplitude of the input sound signal exceeds the first threshold th1 in a period from time TA to time TB. A waveform of the input sound signal reaches the dynamic range dr. Therefore, several divided signals having peak signal levels exceeding the first threshold th1 are present in the period from the time TA to the time TB. Some of the divided signals include clip portions. The amplitude compression processing and the waveform interpolation processing are applied to the divided signals having the peak signal levels exceeding the first threshold th1 and including the clip portions such that the peak signal levels are reduced to the first threshold th1. The amplitude compression processing is applied to the divided signals having the peak signal levels exceeding the first threshold th1 and not including a clip portion such that the peak signal levels are reduced to the first threshold th1. When the peak signal level does not exceed the first threshold th1, the amplitude compression processing is not applied. Consequently, as shown in B of FIG. 7, the amplitude of an output sound signal is limited to the first threshold th1 in a period from time TA′ to time TB′.

In the example shown in A of FIG. 7, an amplitude value of the input sound signal does not exceed the first threshold th1 after the time TB. Therefore, the peak signal level of each of the divided signals does not exceed the first threshold th1. Therefore, the amplitude compression processing is not applied to each of the divided signals. As a result, as shown in B of FIG. 7, a waveform of the output sound signal keeps a waveform of the input sound signal after the time TB′. In other words, attack recovery does not occur. In this way, in the basic amplitude limiting method, since attack recovery does not occur, naturally, noise due to attack recovery can be prevented. In other words, sound of the output sound signal is more natural sound.

In the basic amplitude limiting method, when a peak signal level of a divided signal exceeds the first threshold, the amplitude compression processing is applied to the divided signal. Consequently, the amplitude of the output sound signal is held down to fall within the first threshold. In this example, a value corresponding to a dynamic range of the waveform processing circuit 43 and the signal processing circuits following the waveform processing circuit 43 is adopted as the first threshold. Therefore, in a portion exceeding the first threshold, in some case, distortion is caused by the waveform processing circuit 43 and the signal processing circuits following the waveform processing circuit 43. However, in the basic amplitude limiting method, since the amplitude of the output sound signal can be held down to fall within the first threshold, it is possible to prevent distortion from occurring in the signal.

In the basic amplitude limiting method, for example, a dynamic range of a circuit at a post-stage can be adopted as the first threshold th1. Consequently, the dynamic range of the circuit at the post-stage does not have to be expanded. As a result, compared with the methods disclosed in Patent Documents 1 and 2, it is possible to reduce a circuit size.

However, even if a sound signal includes a portion exceeding the first threshold, in some case, a person listening to sound corresponding to the sound signal does not feel a sense of discomfort in audibility. This is because the human auditory sense is sensitive or insensitive depending on the frequency of sound. In other words, even if a portion exceeds the first threshold, the person does not easily feel a sense of discomfort in audibility depending on the frequency of the portion. Therefore, even if a divided signal has a peak signal level exceeding the first threshold, it is unnecessary to apply the amplitude compression processing to the divided signal when the divided signal is determined as not causing a sense of discomfort in audibility. Since the amplitude compression processing is not applied, for example, envelope information tends to remain. Therefore, it is possible to improve a sound quality.

Therefore, the inventor further devised a method of applying the amplitude compression processing only to a divided signal determined as causing a sense of discomfort in audibility among divided signals having peak signal levels exceeding the first threshold. Such a method is hereinafter referred to as a two-stage threshold amplitude limiting method.

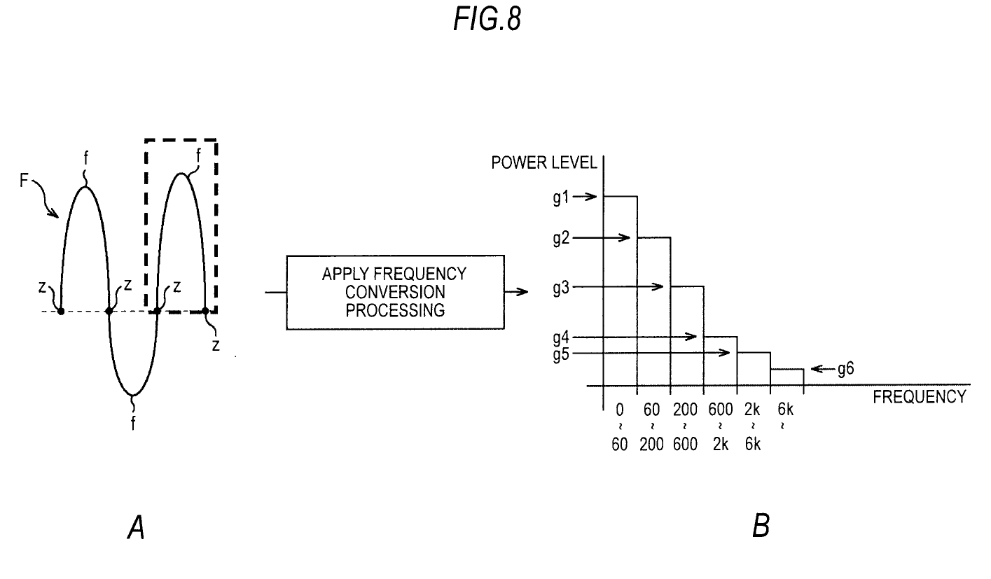

The two-stage threshold amplitude limiting method is explained below with reference to FIGS. 8 to 11. It is assumed that an operation entity is the waveform processing circuit 43 shown in FIG. 5. In other words, it is assumed that the two-stage threshold amplitude limiting method is applied to the waveform processing circuit 43 shown in FIG. 5.

The waveform processing circuit 43 to which the two-stage threshold amplitude limiting method is applied sets a divided signal having a peak signal level exceeding the first threshold as a processing target and applies frequency conversion processing to the processing target to acquire power levels in respective plural bands for the processing target.

### [Explanation of the Frequency Conversion Processing]

FIG. 8 is a diagram for explaining the frequency conversion processing.

A of FIG. 8 is a diagram of an example of an input sound signal. B of FIG. 8 is a diagram of an example of power levels in respective plural bands of a divided signal.

In the example shown in A of FIG. 8, an input sound signal F is divided at respective zero-crosses z, whereby plural divided signals f are obtained. Among the divided signals f, for example, the divided signal f in a dotted line frame in the figure is set as a processing target. A result obtained by applying the frequency conversion processing to the processing target is shown in B of FIG. 8.

In the example shown in B of FIG. 8, power levels g1, g2, g3, g4, g5, and g6 are acquired for respective six bands “0 Hz to 60 Hz”, “60 Hz to 200 Hz”, “200 Hz to 600 Hz”, “600 Hz to 2 kHz”, “2 kHz to 6 kHz”, and “6 kHz or over”. The power levels in the respective bands of the example shown in FIG. 8 are calculated as, for example, a value obtained by integrating all frequency components in the bands among frequencies obtained by applying the frequency conversion processing to the divided signal f.

In this embodiment, since the divided signal f is a digital sound signal, as the frequency conversion processing for the divided signal f, for example, FFT (Fast Fourier Transform) processing is adopted. Therefore, in the following explanation, the frequency conversion processing is represented as FFT processing as appropriate. However, this does not mean that the frequency conversion processing is limited to the FFT processing.

The waveform processing circuit 43 applies filtering processing to power levels in plural bands for the processing-target divided signal f.

### [Explanation of the Filtering Processing]

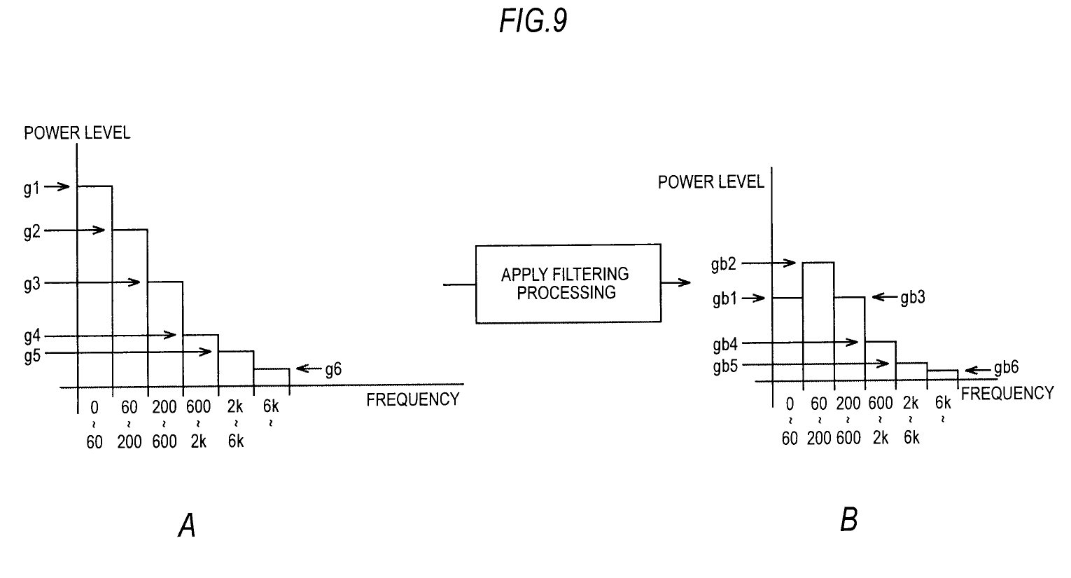

FIG. 9 is a diagram for explaining an example of the filtering processing.

A of FIG. 9 is a diagram of an example of power levels in respective bands and is the same as A of FIG. 8. B of FIG. 9 is a diagram of an example of a result obtained by applying the filtering processing to the power levels in the respective bands of the example shown in A of FIG. 9.

The filtering processing is applied to the power levels g1 to g6 in the respective bands of the example shown in A of FIG. 9, whereby power levels gb1 to gb6 in the respective bands of the example shown in B of FIG. 9 is obtained.

In this example, among the power levels in the respective bands, a degree of decrease from the power level g1 to the power level gb1 in the band “0 Hz to 60 Hz” and a degree of decrease from the power level g2 to the power level gb2 in the band “60 Hz to 200 Hz” are large.

In the filtering processing, a filter adjusted to the human audibility characteristic is used. For example, a filter having an IHF (Institute of High Fedelity Inc. standard) A curve of IEC (International Electrotechnical commission) 61672-1 is used. In the filter, frequency characteristics at a frequency equal to or lower than 200 Hz and a frequency equal to or higher than 10 kHz are set small according to the human audibility characteristic. Therefore, in the example shown in FIG. 9, the power levels in the band “0 Hz to 60 Hz” and the band “60 Hz to 200 Hz” substantially decrease.

The waveform processing circuit 43 detects power levels in the respective bands after the filtering processing. The waveform processing circuit 43 compares the power levels in the respective plural bands after the filtering processing and the second threshold in the respective bands. The waveform processing circuit 43 determines whether there is a power level exceeding the second threshold to determine whether there is a problem in audibility. The waveform processing circuit 43 performs the amplitude compression processing on the basis of a result of the determination. A series of processing from the comparison processing for the power levels in the respective bands after the filtering processing to the amplitude compression processing is hereinafter generally referred to as audibility determination and compression processing.

### [Explanation of the Audibility Determination and Compression Processing]

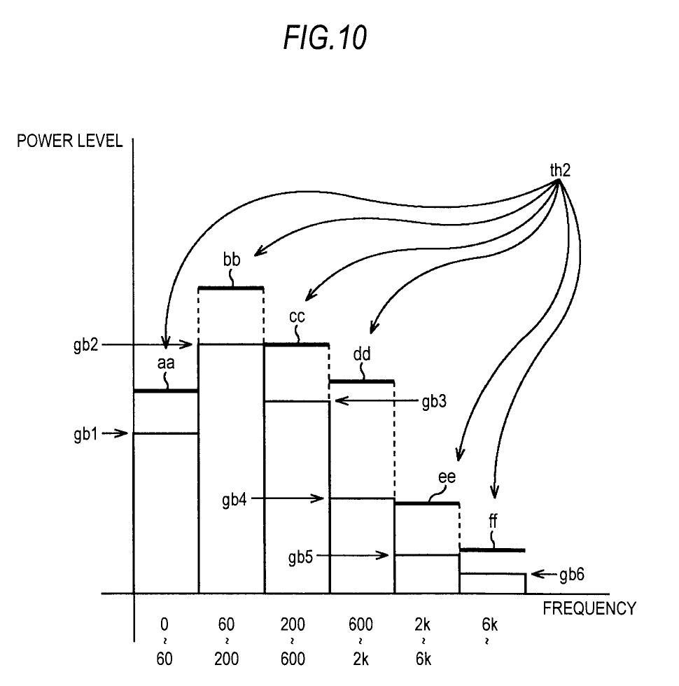

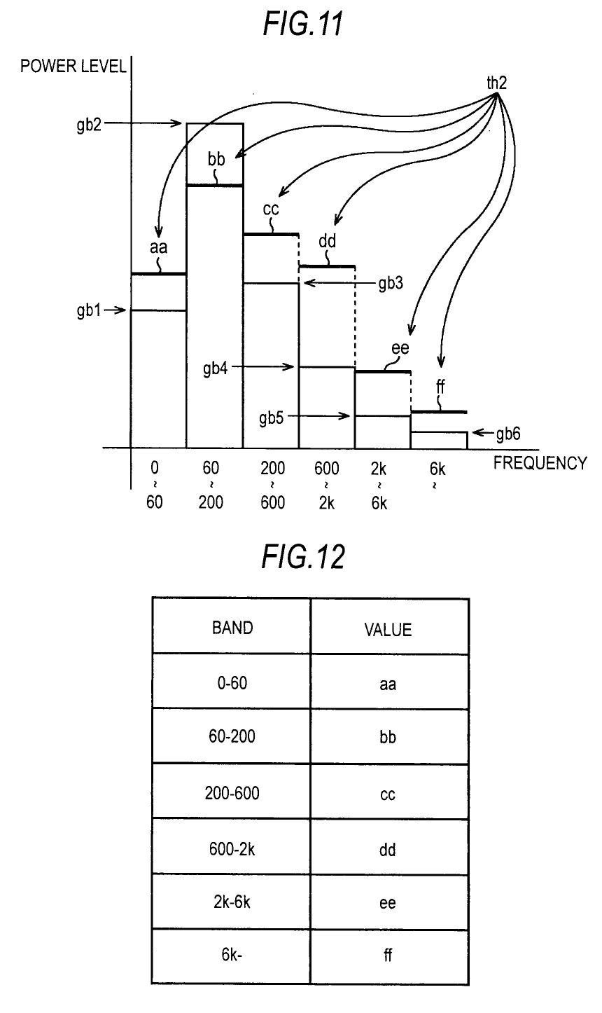

FIGS. 10 and 11 are diagrams for explaining the audibility determination and compression processing. Power levels in the respective bands of the example shown in FIGS. 10 and 11 are the same as the power levels in the respective bands of the example shown in B of FIG. 9.

In the example shown in FIGS. 10 and 11, a second threshold th2 includes values aa to ff in the respective bands “0 Hz to 60 Hz” to “6 kHz or over”. The respective values aa to ff in the respective bands of the second threshold th2 are set to, for example, power levels assumed to start to cause a sense of discomfort in audibility in the respective bands “0 Hz to 60 Hz” to “6 kHz or over”.

In the example shown in FIG. 10, the power levels gb1 to gb6 in the respective bands do not respectively exceed the values aa to ff in the respective bands of the second threshold th2. In such a case, i.e., when none of the power levels gb1 to gb6 in the respective bands exceeds the values in the respective bands of the second threshold th2, it is determined that there is no problem in audibility. The amplitude compression processing is not applied to a divided signal.

On the other hand, in the example shown in FIG. 11, the power level gb2 in the band “60 Hz to 200 Hz” exceeds the value bb in the band of the second threshold th2. The power levels gb1 and gb3 to gb6 in the other respective bands do not respectively exceed the values aa and cc to ff in the other respective bands of the second threshold th2. In such a case, i.e., when there is a power level exceeding the value of the band of the second threshold th2 among the power levels gb1 to gb6 in the respective bands, it is determined that there is a problem in audibility. The amplitude compression processing is applied to a divided signal such that a peak signal level of the divided signal is reduced to fall within the first threshold th1.

When the number of power levels exceeding the values in the respective bands of the second threshold th2 is smaller than an arbitrary predetermined number, it is also possible not to apply the amplitude compression processing to a divided signal.

In this embodiment, it is assumed that the waveform processing circuit 43 stores the values in the respective bands of the second threshold in a table in the inside thereof.

[An Example of the Table in which the Values in the Respective Bands of the Second Threshold are Stored]

FIG. 12 is a diagram of an example of the table in which the values in the respective bands of the second threshold are stored. As shown in FIG. 11, in the table, the values aa to ff in the respective bands of the second threshold th2 are respectively associated with the bands “0 Hz to 60 Hz” to “6 kHz or over”. However, a method of storing the values in the respective bands of the second threshold is not specifically limited.

The waveform processing circuit 43 performs, in addition to the determination concerning the power levels in the respective bands after the filtering processing, the determination concerning the clip portion in the basic amplitude limiting method. The waveform processing circuit 43 determines processing for a divided signal on the basis of results of the determinations.

[An Example of a Processing Result of the Waveform Processing Circuit 43 to which the Two-Stage Threshold Amplitude Limiting Method is Applied]

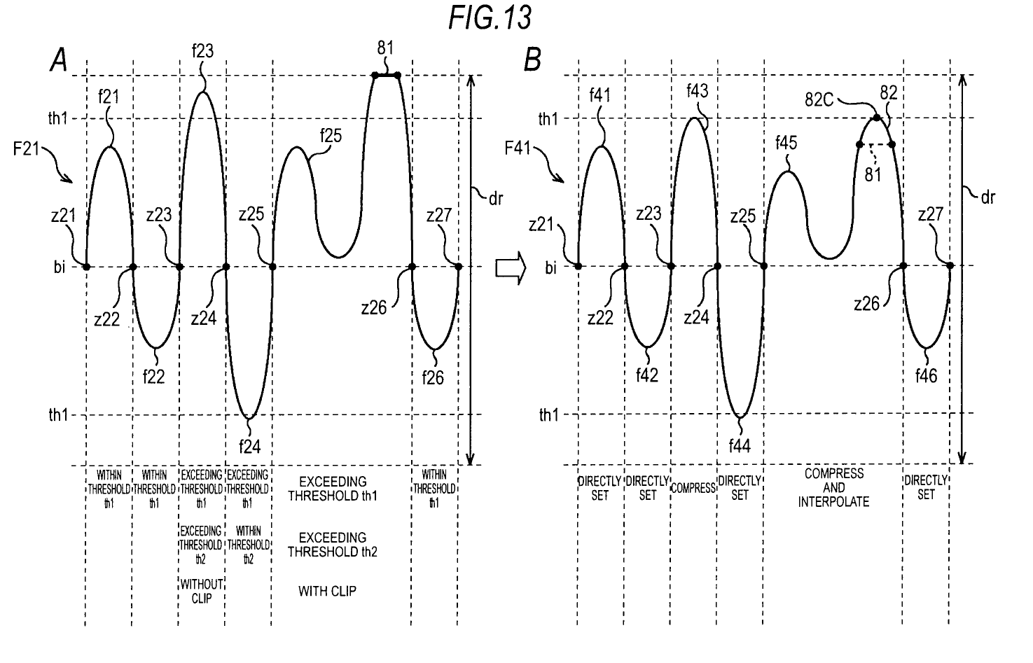

FIG. 13 is a diagram for explaining an example of a processing result of the waveform processing circuit 43 to which the two-stage threshold amplitude limiting method is applied.

A of FIG. 13 is a diagram of an example of a part of an input sound signal. B of FIG. 13 is a diagram of an example of a part of an output sound signal.

In the example shown in A of FIG. 13, zero-crosses z21 to z27 are detected for an input sound signal F21. The input sound signal F21 is divided at the zero-crosses z21 to z27. As a result, divided signals f21 to f26 are obtained.

Peak signal levels in the divided signals f21, f22, and f26 fall within the first threshold th1. A state in which a peak signal level in a divided signal falls within the first threshold th1 is hereinafter described as “within the threshold th1” as appropriate according to the description in the figure. Peak signal levels in the divided signals f23, f24, and f25 exceed the first threshold th1. A state in which a peak signal level in a divided signal exceeds the first threshold th1 is hereinafter described as “exceeding the threshold th1” as appropriate according to the description in the figure.

Some of power levels in the respective bands of the divided signals f23 and f25 exceed the second threshold th2. A state in which some of power levels in respective bands of a divided signal exceed the second threshold th2 in “exceeding the threshold th1” is hereinafter described as “exceeding the threshold th2” as appropriate according to the description in the figure. All power levels in respective bands of the divided signal f24 fall within the second threshold th2. A state in which all power levels in respective bands of a divided signal fall within the second threshold th2 in “exceeding the threshold th1” is hereinafter described as “within the threshold th2” as appropriate according to the description in the figure. The divided signal f23 does not include a clip portion. A state in which a divided signal does not include a clip portion in “exceeding the threshold th1” is hereinafter described as “without a clip” as appropriate according to the description in the figure. The divided signal f25 includes a clip portion 81. A state in which a divided signal includes a clip portion in “exceeding the threshold th1” is hereinafter described as “with a clip” as appropriate according to the description in the figure.

Processing results explained below are obtained for the divided signals f21 to f26.

Since a state of the divided signals f21, f22, and f26 is “within the threshold th1”, the divided signals f21, f22, and f26 are subjected to neither the amplitude compression processing nor the waveform interpolation processing and is directly set as divided signals f41, f42, and f46.

A state of the divided signal f23 is “exceeding the threshold th1”, “exceeding the threshold th2”, and “without a clip”. Therefore, the amplitude compression processing is applied to the divided signal f23 such that a peak level signal in the divided signal f23 coincides with the first threshold th1″. A signal obtained as a result of the amplitude compression processing is a divided signal f43. A state of the divided signal f24 is “exceeding the threshold th1” and “within the threshold th2”. The divided signal f24 is subjected to neither the amplitude compression processing nor the waveform interpolation processing and is directly set as the divided signal f44. In other words, a sound signal having a peak signal level exceeding the first threshold th1 is the divided signal f44. A state of the divided signal f25 is “exceeding the threshold th1”, “exceeding the threshold th2”, and “with a clip”. Therefore, the amplitude compression processing is applied to the divided signal f25 such that a peak signal level in the divided signal f25 is smaller than the first threshold th1. The waveform interpolation processing is applied to the divided signal f25 after the amplitude compression processing. Specifically, for example, waveform interpolation processing for adding a waveform 82 passing a point 82C having the first threshold th1 as an amplitude value is applied to the clip portion 81 of the divided signal f25. A signal obtained as a result of applying the amplitude compression processing and the waveform interpolation processing to the divided signal f25 in this way, i.e., a signal having a peak signal level set to the first threshold th1 is the divided signal f45.

As explained above, in the two-stage threshold amplitude limiting method, it is possible not to apply the amplitude compression processing and the waveform interpolation processing to a divided signal “within the threshold th2”, i.e., a divided signal determined as not causing a problem in audibility. Consequently, an original waveform can be kept as much as possible and sound more faithful to original sound is obtained. Even if a divided signal is “exceeding the threshold th1”, it is possible not to apply the amplitude compression processing to the divided signal when the divided signal is a divided signal “within the threshold th2” determined as not causing a problem in audibility. Consequently, since envelope information tends to remain, a sound quality can be improved.

In the two-stage threshold amplitude limiting method, as in the basic amplitude limiting method, for example, a dynamic range of a circuit at a post-stage can be adopted as the first threshold th1. Consequently, the dynamic range of the circuit at the post-stage does not have to be expanded. As a result, it is possible to reduce a circuit size compared with the methods disclosed in Patent Documents 1 and 2.

In the two-stage threshold amplitude limiting method, a method of detecting power levels in respective bands after the filtering processing is adopted. Therefore, even when a signal including a large number of noise components is input, unless there is a sense of discomfort in audibility (sound is hard to hear), the input sound signal is directly output as an output sound signal. Therefore, it is possible to suppress a phenomenon that occurs in the peak detection method in which the amplitude of an output sound signal is excessively held down.

A detailed configuration example of the waveform processing circuit 43 to which the two-stage threshold amplitude limiting method explained above is applied is explained below.

[A Detailed Configuration Example of the Waveform Processing Device to which the Two-Stage Threshold Amplitude Limiting Method is Applied]

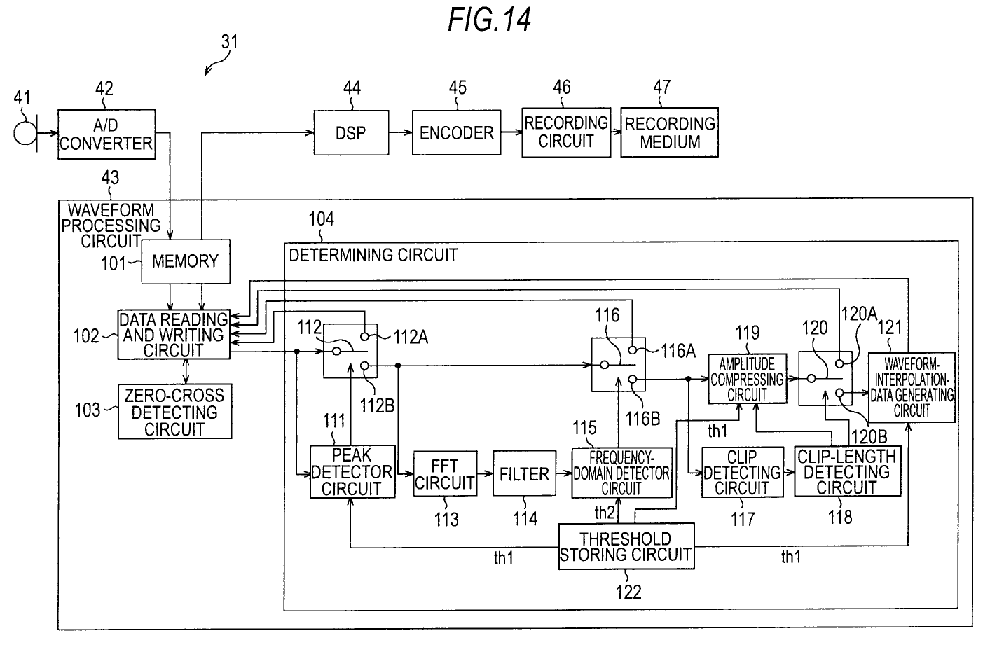

FIG. 14 is a block diagram of a detailed configuration example of the waveform processing circuit 43.

A digital sound signal is input to the waveform processing circuit 43 of the example shown in FIG. 14.

The waveform processing circuit 43 includes a memory 101, a data reading and writing circuit 102, a zero-cross detecting circuit 103, and a determining circuit 104. The determining circuit 104 includes a peak detector circuit 111, a switch 112, an FFT circuit 113, a filter 114, a frequency-domain detector circuit 115, and a switch 116. The determining circuit 104 further includes a clip detecting circuit 117, a clip-length detecting circuit 118, an amplitude compressing circuit 119, a switch 120, a waveform-interpolation-data generating circuit 121, and a threshold storing circuit 122.

Functions of the components of the waveform processing circuit 43 are explained together with the following explanation of processing by the waveform processing circuit 43.

### [A Processing Example of the Waveform Processing Circuit]

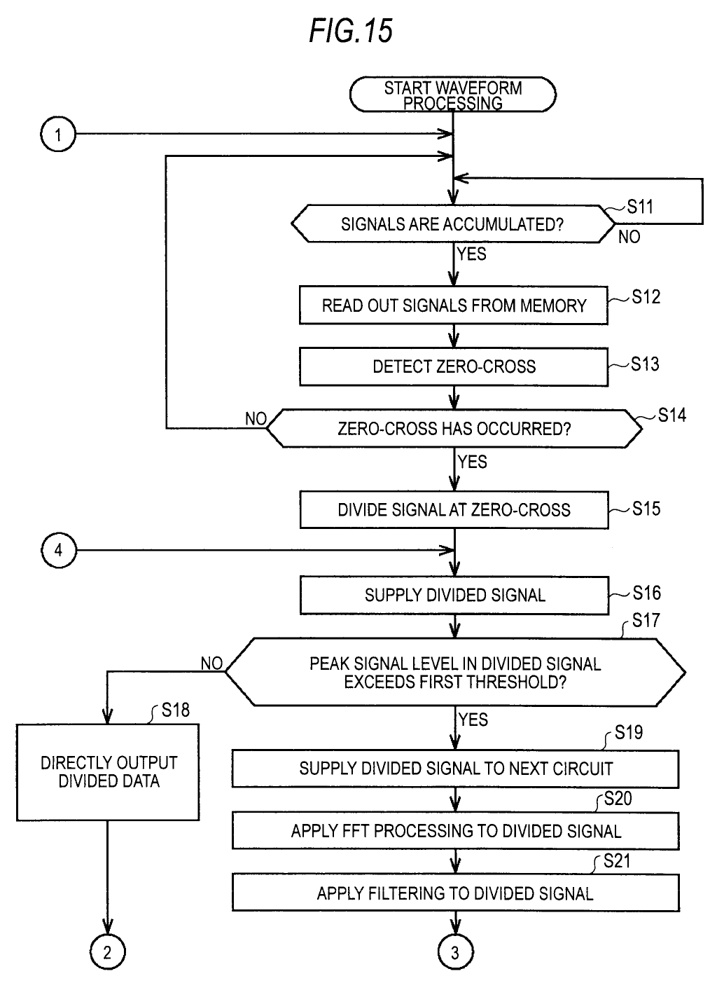

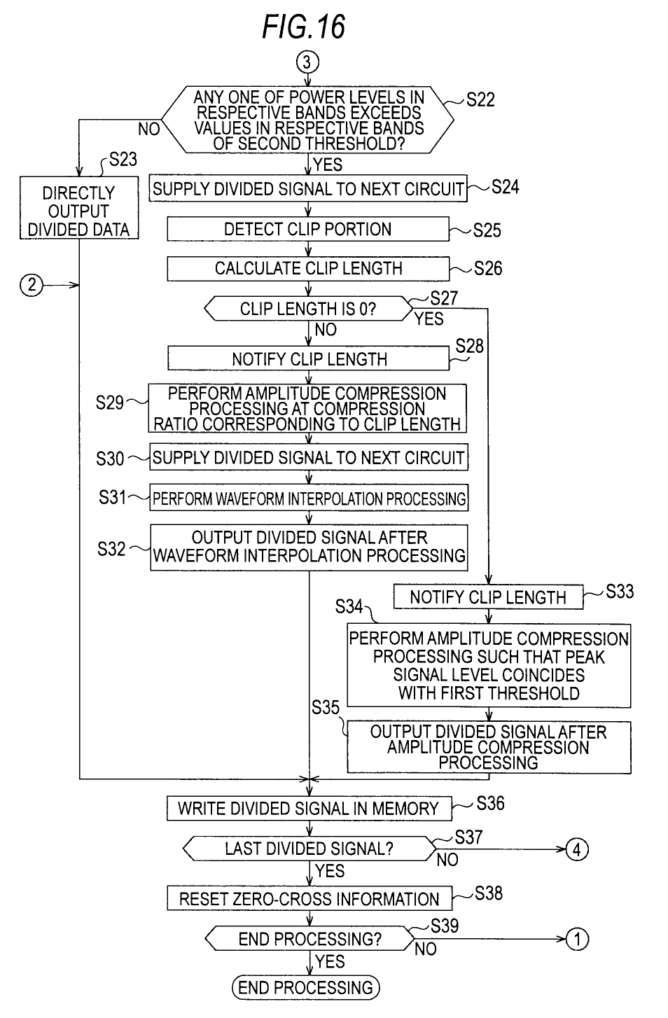

An example of processing by the waveform processing circuit 43 (hereinafter referred to as waveform processing) is explained with reference to flowcharts shown in FIGS. 15 and 16.

The threshold storing circuit 122 stores the first threshold th1 and the second threshold th2. In the following explanation, it is assumed that the peak detector circuit 111, the amplitude compressing circuit 119, and the waveform-interpolation-data generating circuit 121 read out the threshold th1 from the threshold storing circuit 122 in advance and hold the threshold th1 in the inside thereof. The frequency-domain detector circuit 115 reads out the second threshold th2 from the threshold storing circuit 122 in advance and stores the second threshold th2 in the inside thereof.

The memory 101 sequentially accumulates digital sound signals from the A/D converter 42. In step S11, the data reading and writing circuit 102 determines whether sound signals are accumulated in the memory 101.

For example, unless a predetermined amount of sound signals are accumulated in the memory 101, the processing is returned to step S11. In other words, the determination processing in step S11 is repeated until the predetermined amount of sound signals are accumulated in the memory 101.

Thereafter, when the data reading and writing circuit 102 determines in step S11 that the predetermined amount of sound signals are accumulated in the memory 101 (YES in step S11), the processing proceeds to step S12. In step S12, the data reading and writing circuit 102 reads out the predetermined amount of sound signals from the memory 101 and supplies the sound signals to the zero-cross detecting circuit 103 as an input sound signal. In step S13, the zero-cross detecting circuit 103 detects, as a zero-cross point, a position between points before and after a point where a signal level crosses a bias among data points forming the input sound signal and stores information concerning the position as zero-cross information. In step S14, the data reading and writing circuit 102 determines whether a zero-cross has occurred.

As long as the number of zero-crosses stored as the zero-cross information is zero, the data reading and writing circuit 102 determines in step S14 that a zero-cross has not occurred (NO in step S14). The processing is returned to step S11.

On the other hand, when the number of zero-crosses stored as zero-cross information is equal to or larger than one, the data reading and writing circuit 102 determines in step S14 that a zero-cross has occurred (YES in step S14). The processing proceeds to step S15. In step S15, the data reading and writing circuit 102 divides the input sound signal accumulated in the memory 101 at the one or more zero-crosses stored as the zero-cross information. In other words, divided plural signals are the divided signals explained above. In step S16, the data reading and writing circuit 102 reads out predetermined one of the plural divided signals from the memory 101 and supplies the divided signal to the peak detector circuit 111 and the switch 112 of the determining circuit 104. In step S17, the peak detector circuit 111 determines whether a peak signal level in the divided signal exceeds the first threshold th1.

When the data reading and writing circuit 102 determines in step S17 that the peak signal level in the divided signal does not exceed the first threshold th1 (NO in step S17), the processing proceeds to step S18. The peak detector circuit 111 changes over the switch 112 to a terminal 112A. Consequently, the divided signal (“within the threshold th1”) is directly output to the data reading and writing circuit 102 without being subjected to amplitude compression. Thereafter, the processing proceeds to step S36. Processing in step S36 and subsequent steps is explained later.

On the other hand, when the data reading and writing circuit 102 determines in step S17 that the peak signal level in the divided signal exceeds the first threshold th1 (YES in step S17), the processing proceeds to step S19. The peak detector circuit 111 changes over the switch 112 to a terminal 112B. Consequently, the divided signal is supplied to the FFT circuit 113 and the switch 116.

In step S20, the FFT circuit 113 applies FFT processing to the divided signal to acquire power levels in respective plural bands for the divided signal and supplies the power levels to the filter 114. In step S21, the filter 114 applies filtering processing to the power levels in the respective plural bands and then supplies the power levels to the frequency-domain detector circuit 115. In step S22, the frequency-domain detector circuit 115 determines whether any one of the power levels in the respective plural bands exceeds the values in the respective bands of the second threshold.

When the frequency-domain detector circuit 115 determines in step S22 that none of the power levels in the respective bands exceeds the values in the respective bands of the second threshold (NO in step S22), the processing proceeds to step S23. The frequency-domain detector circuit 115 changes over the switch 116 to a terminal 116A. Consequently, the divided signal (“exceeding the threshold th1” and “within the threshold th2”) is directly output to the data reading and writing circuit 102 without being subjected to amplitude compression. In other words, the divided signal exceeding the first threshold th1 is output to the data reading and writing circuit 102. Thereafter, the processing proceeds to step S36. Processing in step S36 and subsequent steps is explained later.

On the other hand, when the frequency-domain detector circuit 115 determines in step S22 that any one of the power levels in the respective plural bands exceeds the values in the respective bands of the second threshold (YES in step S22) the processing proceeds to step S24. In step S24, the frequency-domain detector circuit 115 changes over the switch 116 to a terminal 116B. Consequently, the divided signal is supplied to the clip detecting circuit 117 and the amplitude compressing circuit 119. In step S25, the clip detecting circuit 117 detects a clip portion of a waveform of the divided signal. For example, when the waveform processing circuit 43 includes a 4-bit circuit, the clip detecting circuit 117 detects, as a clip portion, a portion where “1111” or “0000” continues in the divided signal. The waveform processing circuit 43 can include a circuit of an arbitrary number of bits.

In step S26, the clip-length detecting circuit 118 calculates time length of the clip portion (hereinafter referred to as clip length). However, the clip-length detecting circuit 118 sets the clip length to zero for a divided signal in which a clip portion is not detected. In step S27, the clip-length detecting circuit 118 determines whether the clip length of the divided signal is zero.

When the clip-length detecting circuit 118 determines in step S27 that the clip length of the divided signal is not zero (NO in step S27), the processing proceeds to step S28. The clip-length detecting circuit 118 notifies the amplitude compressing circuit 119 of the (non-zero) clip length of the divided signal. Thereafter, the processing proceeds to step S29.

On the other hand, when the clip-length detecting circuit 118 determines in step S27 that the clip length of the divided signal is zero (YES in step S27), the processing proceeds to step S33. Processing in step S33 and subsequent steps is explained later.

In step S29, the amplitude compressing circuit 119 applies the amplitude compression processing to the divided signal at a compression ratio corresponding to the (non-zero) clip length and then supplies the divided signal to the switch 120.

### [A Reason for Applying the Amplitude Compression Processing at the Compression Ratio Corresponding to the Clip Length]

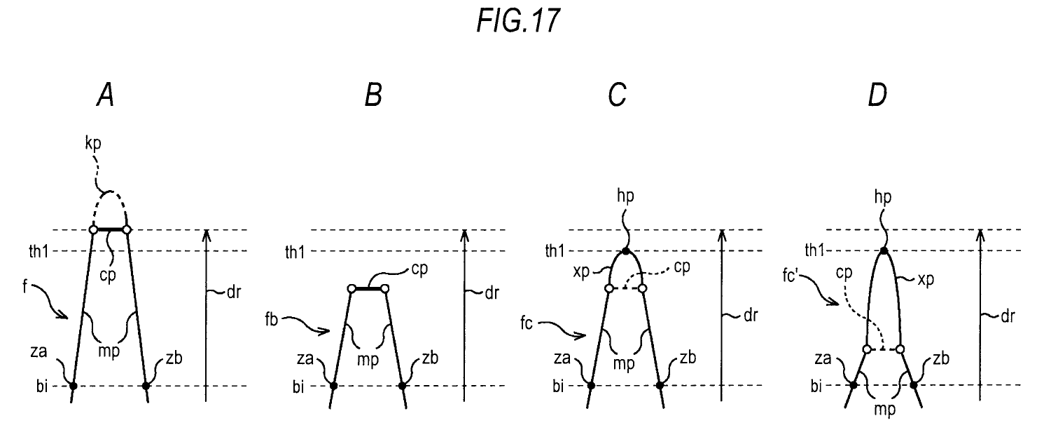

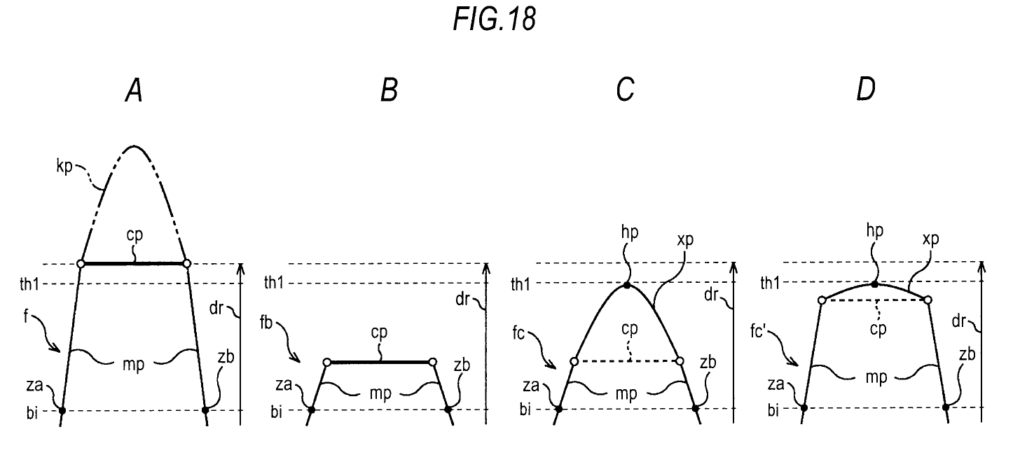

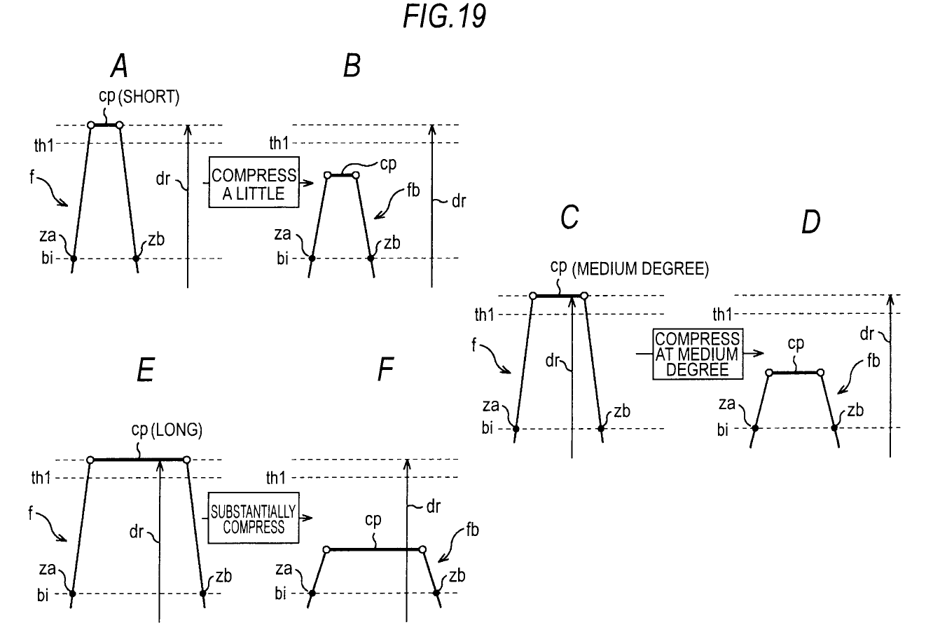

A reason for applying the amplitude compression processing at the compression ratio corresponding to the clip length is explained with reference to FIGS. 17 and 18.

FIG. 17 is a diagram for explaining a reason for applying the amplitude compression processing at a small compression ratio when the clip length is small.

A of FIG. 17 is a diagram of an example of a divided signal (before the amplitude compression processing). B of FIG. 17 is a diagram of an example of the divided signal after the amplitude compression processing. C and D of FIG. 17 are diagrams of examples of the divided signal after the waveform interpolation processing.

In the example shown in A of FIG. 17, a divided signal f including a clip portion cp is set as a processing target. The processing-target divided signal f is divided at a zero-cross za and a zero-cross zb.

As shown in A of FIG. 17, it is assumed that the length of the clip portion cp of the divided signal f is, for example, equal to or smaller than 10% of the length of the entire divided signal f. In this case, it is assumed that an area of the portion of a waveform kp that is lost because of the clip portion cp (an area surrounded by the waveform kp and the clip portion cp) is small. In B of FIG. 17, a divided signal fb obtained as a result of applying the amplitude compression processing to the divided signal f at a small compression ratio is shown. In C of FIG. 17, a divided signal fc obtained as a result of applying the waveform interpolation processing to the clip portion cp of the divided signal fb is shown. In the waveform interpolation processing, waveform interpolation processing for adding a waveform xp passing a point hp having the first threshold th1 as an amplitude value is applied to the clip portion cp of the divided signal fb after the amplitude compression processing. The point hp is hereinafter referred to as waveform interpolation point hp as appropriate. The waveform xp is hereinafter referred to as interpolation waveform xp as appropriate. A portion mp other than the clip portion cp (hereinafter referred to as non-clip portion) of the divided signal f is deformed by the amplitude compression processing. However, the deformation is minimized. As a result, deterioration in a sound quality can be minimized. On the other hand, in D of FIG. 17, a divided signal fc′ obtained as a result of applying the amplitude compression processing to the same divided signal f (before the amplitude compression processing) at a large compression ratio and applying the same waveform interpolation processing thereto is shown. The interpolation waveform xp of the divided signal fc′ has a shape extended vertically. Therefore, it is likely that a joint between the interpolation waveform xp and the non-clip portion mp in the divided signal fc′ is unnatural to cause distortion in the signal.

FIG. 18 is a diagram for explaining a reason for applying the amplitude compression processing at a large compression ratio when the clip length is large.

A of FIG. 18 is a diagram of an example of a divided signal (before the amplitude compression processing). B of FIG. 18 is a diagram of an example of the divided signal after the amplitude compression processing. C and D of FIG. 18 are diagrams of examples of the divided signal after the waveform interpolation processing.

As shown in A of FIG. 18, it is assumed that the length of the clip portion cp of the divided signal f occupies 80% or more of the length of the entire signal f. In this case, it is assumed that an area of the portion of the waveform kp lost because of the clip portion cp is large. This assumption is opposite to the assumption in the case of the short clip portion cp. In B of FIG. 18, the divided signal fb obtained as a result of applying the amplitude compression processing to the divided signal f at a large compression ratio is shown. In C of FIG. 18, the divided signal fc obtained as a result of applying the waveform interpolation processing to the clip portion cp of the divided signal fb is shown. In the waveform interpolation processing, waveform interpolation processing for adding the waveform xp passing the point hp having the first threshold th1 as an amplitude value is applied to the divided signal fb after the amplitude compression processing. With the amplitude compression processing, an interpolation amount of the waveform xp increases compared with the case of the short clip portion cp. On the other hand, in D of FIG. 18, the divided signal fc′ obtained by applying the amplitude compression processing to the same divided signal f (before the amplitude compression processing) at a small compression ratio and applying the same waveform interpolation processing thereto is shown. It is likely that a joint of the interpolation waveform xp and the non-clip portion mp in the divided signal fc′ is unnatural to cause distortion in the signal.

As explained above, the amplitude compression processing is performed as the compression ratio corresponding to the clip length for the purpose of smoothing a joint with an interpolation waveform to prevent distortion from occurring in a signal.

The amplitude compression processing performed at the compression ratio corresponding to the clip length is basically processing explained below.

### [Explanation of an Example of the Amplitude Compression Processing Performed at the Compression Ratio Corresponding to the Clip Length]

FIG. 19 is a diagram for explaining the amplitude compression processing performed at the compression ratio corresponding to the clip length.

A, C, and E of FIG. 19 are diagrams of a divided signal (before the amplitude compression processing). B, D, and F of FIG. 19 are diagrams of the divided signal after the amplitude compression processing.

As shown in A of FIG. 19, when the length of the clip portion cp of the divided signal f is small, the amplitude compression processing is applied to the divided signal f at a small compression ratio. As a result, the divided signal fb of an example shown in B of FIG. 19 is obtained. A signal level of the divided signal fb is compressed a little. As shown in C of FIG. 19, when the length of the clip portion cp of the divided signal f is medium, the amplitude compression processing is applied to the divided signal f at a medium compression ratio. As a result, the divided signal fb of an example shown in C of FIG. 19 is obtained. A signal level of the divided signal fb is compressed at a medium degree. As shown in E of FIG. 19, when the length of the clip portion cp of the divided signal f is large, the amplitude compression processing is applied to the divided signal f at a large compression ratio. As a result, the divided signal fb of an example shown in F of FIG. 19 is obtained. A signal level of the divided signal fb is substantially compressed.

As an example of the amplitude compression processing performed at the compression ratio corresponding to the clip length, amplitude compression processing for setting a compression ratio proportionally to clip length is explained. In this example, the compression ratio of the amplitude compression processing is referred to as compression amount and a value of the compression amount is described as att. The compression amount att is indicated by, for example, the following Formula (1):

att=th1×ct/cmax (unit: dB) (1)

In Formula (1), th1 represents the first threshold (unit: dB), ct represents a value of clip length of a divided signal (unit: second), and cmax represents an assumed maximum of the clip length (hereinafter referred to as maximum clip length) (unit: second). Since the clip length is treated in second units, naturally, Formula (1) can also be applied to an analog sound signal.

A calculation example of the compression amount att for a digital sound signal is explained below. Clip length for the digital sound signal is described as the number of samples. For example, maximum clip length described as time length is set to one second and a sampling frequency is set to 48 kHz. In this case, the maximum clip length (described by the number of samples) is 48000. When the first threshold th1 described as gradation is set to 256, the first threshold th1 (described in dB units) is −48.2 dB (=20 log (1/256)). In this case, the compression amount att is represented by the following Formula (2):

−48.2×n/48000 (unit: dB) (2)

In Formula (2), n represents the clip length (described by the number of samples) of the divided signal f.

The amplitude compression processing is applied to a divided signal by using the compression amount att of Formula (2). Consequently, when clip length of the divided signal is small, the amplitude in the divided signal can be compressed a little. When clip length of the divided signal is large, the amplitude in the divided signal can be substantially compressed.

When the clip length exceeds the maximum clip length, for example, it is possible to adopt a method of determining that the entire divided signal is a clip portion and compressing the amplitude with a compression amount of the maximum clip length. When the method is adopted, the compression amount of the maximum clip length is −48.2 dB (=−48.2×48000/48000). As another method, it is also possible to adopt a method of setting processing performed when the clip length exceeds the maximum clip length as exceptional processing and replacing, in the exceptional processing, a waveform of the entire divided signal with another waveform. As another method of calculating a compression ratio corresponding to clip length, for example, it is also possible to adopt a method explained below. Specifically, it is possible to adopt a method of storing in advance a table value for associating a compression ratio to clip length and calculating a compression ratio for clip length of a divided signal referring to the table value.

Referring back to FIG. 16, in step S30, the clip-length detecting circuit 118 changes over the switch 120 to the terminal 120B. Consequently, the divided signal after the amplitude compression processing from the amplitude compressing circuit 119 is supplied to the waveform-interpolation-data generating circuit 121. In step S31, the waveform-interpolation-data generating circuit 121 applies waveform interpolation processing for adding a waveform passing a point having the first threshold th1 as an amplitude value to the clip portion of the divided signal.

### [An Example of the Waveform Interpolation Processing]

A detailed example of the waveform interpolation processing is explained with reference to FIG. 20.

A of FIG. 20 is a diagram of an example of a divided signal (before the amplitude compression processing). B of FIG. 20 is a diagram of an example of the divided signal after the amplitude compression processing. C of FIG. 20 is a diagram of an example of the divided signal after the waveform interpolation processing.

In the example shown in A of FIG. 20, a portion where a waveform of the divided signal f reaches the dynamic range dr to be a straight line is detected as the clip portion cp. Therefore, the amplitude compression processing is applied to the divided signal f. As a result, the divided signal fb of the example shown in B of FIG. 20 is obtained. A start point sp and an end point ep are detected for the clip portion cp of the divided signal fb. The waveform interpolation processing is applied to the divided signal fb. As a result, the divided signal fc of the example shown in C of FIG. 20 is obtained. The waveform interpolation processing is, for example, processing explained below. A midpoint of a straight line connecting the start point sp and the end point ep is calculated as the center of the clip portion cp. The waveform interpolation point hp is determined on the basis of a sampling position in the center of the clip portion cp (a position in the lateral direction in the figure) and an amplitude value of the first threshold th1 (a position in the longitudinal direction in the figure). For example, among points in sampling positions same as the center of the clip portion cp, a point having the first threshold th1 as an amplitude value is determine as the waveform interpolation point hp. The interpolation waveform xp connecting the start point sp, the endpoint ep, and the waveform interpolation point hp is created and added to the clip portion cp.

When plural clip portions cp are present in the divided signal f, all the clip portions cp are grasped in advance and the waveform interpolation processing is repeatedly applied to the respective plural clip portions cp.

As an interpolation method for connecting the three points of the start point sp, the end point ep, and the waveform interpolation point hp in the detailed example of the waveform interpolation processing explained above, in this embodiment, for example, a spline interpolation method is adopted. The spline interpolation method is explained later. However, the interpolation method is not specifically limited. For example, it is also possible to adopt, for example, an interpolation method employing a Lagrange's function, an interpolation method for calculating an arc passing the points, and an interpolation method for simply connecting the points with a straight line. It is also possible to adopt, for example, an interpolation method for storing an interpolation waveform in a not-shown memory in advance, transforming the interpolation waveform according to clip length or a compression ratio, and adding the interpolation waveform after the transformation to a clip portion.

Referring back to FIG. 16, in step S32, the waveform-interpolation-data generating circuit 121 outputs the divided signal after the waveform interpolation processing to the data reading and writing circuit 102. Consequently, a divided signal obtained as a result of applying the amplitude compression processing and the waveform interpolation processing to the divided signal (“exceeding the threshold th1”, “exceeding the threshold th2”, and “with a clip”) is output to the data reading and writing circuit 102. In other words, a divided signal, a peak signal level of which is the first threshold th1, is output to the data reading and writing circuit 102. Thereafter, the processing proceeds to step S36. Processing in step S36 and subsequent steps is explained later.

When the clip-length detecting circuit 118 determines in step S27 that the clip length of the divided signal is zero (YES in step S27), the processing proceeds to step S33. In step S33, the clip-length determining circuit 118 notifies the amplitude compressing circuit 119 of the (zero) clip length of the divided signal. In step S34, the amplitude compressing circuit 119 applies the amplitude compression processing to the divided signal such that the peak signal level of the divided signal coincides with the first threshold th1. Specifically, for example, the amplitude compressing circuit 119 applies the amplitude compression processing to the divided signal with the compression amount att of the following Formula (3) :

att=dmax/th1 (unit: dB) (3)

In Formula (3), dmax (unit: dB) represents the peak signal level of the divided signal and th1 represents the first threshold th1 (unit: dB).

In step S35, the clip-length detecting circuit 118 changes over the switch 120 to the terminal 120A. Consequently, a divided signal obtained as a result of applying the amplitude compression processing to the divided signal (“exceeding the threshold th1”, “exceeding the threshold th2”, and “without a clip”) is output to the data reading and writing circuit 102. In other words, a divided signal, a peak value of which is the first threshold th1, is output to the data reading and writing circuit 102.

In step S36, the data reading and writing circuit 102 writes a divided signal from the determining circuit 104 in the memory 101. In step S37, the data reading and writing circuit 102 determines whether the divided signal from the determining circuit 104 is the last divided signal.

When the data reading and writing circuit 102 determines in step S37 that the divided signal from the determining circuit 104 is not the last divided signal (NO in step S37), the processing is returned to step S16.

On the other hand, when the data reading and writing circuit 102 determines in step S37 that the divided signal from the determining circuit 104 is the last divided signal (YES in step S37), the processing proceeds to step S38. The data reading and writing circuit 102 resets the zero-cross information. In step S39, the data reading and writing circuit 102 determines whether the processing should be ended.

Unless an instruction for processing end based on, for example, user operation is supplied to the waveform processing circuit 43, the data reading and writing circuit 102 determines in step S39 that the processing is not ended (NO in step S39). The processing is returned to step S11 in FIG. 15.

On the other hand, when the instruction for processing end based on, for example, user operation is supplied to the waveform processing circuit 43, the data reading and writing circuit 102 determines in step S39 that the processing is ended (YES in step S39). The waveform processing is ended.

The waveform processing circuit 43 in this example is grasped as including a digital circuit of the FF format. In other words, a circuit area of the waveform processing circuit 43 can be reduced and cost thereof can be held down compared with the AGC circuit in the past (the analog circuit in the FB format). In the waveform processing circuit 43, it is unnecessary to consider setting of attack recovery. Therefore, it is easy to design the circuit.

The spline interpolation method as the interpolation method for connecting the three points of the start point sp, the end point ep, and the waveform interpolation point hp is explained.

The spline interpolation method is an interpolation method for smooth1y connecting discrete data points using a belt (spline) formed by an elastic member. The spline draws a curve conforming to a characteristic of the elastic member through the points when several points at both ends and in the middle thereof are supported. Mathematically, the spline is given as a k-th (k is an integer value equal to or larger than 1) order polynomial passing the respective data points. In the k-th order polynomial, a k−1th order differential coefficient is linear. As the polynomial, a third-order polynomial is often used. Therefore, a third-order spline interpolation method employing the third-order polynomial is explained below.

In the following explanation, x and y coordinates are used. Among N (N is an integer value equal to or larger than 2) data points, an x coordinate value for a jth (j is an integer value equal to or larger than 0) data point in order of smallness of an x coordinate value is described as xⱼ. An entire section in the x axis direction of the spline is hereinafter referred to as spline section. The spline section is divided at the respective data points. In the third-order spline interpolation method, third-order polynomials are given to respective divided plural sections. The polynomials for the respective sections are referred to as divided interpolation formulas. Among the divided interpolation formulas, a divided interpolation formula sⱼ(x) for the section divided by jth and j+1th data points is represented by the following Formula (4):

sⱼ(x)=aⱼ(x−xⱼ)³+bⱼ(x−xⱼ)²+cⱼ(x−xⱼ)+dⱼ (j=0, 1, 2, . . . , N−1) (4)

In Formula (4), aⱼ, bⱼ, cⱼ, and dⱼ represent unknown coefficients.

N divided interpolation formulas are present. Four unknown coefficients are present for each of the N divided interpolation formulas. Therefore, 4N unknown coefficients are present in total. To calculate all the 4N unknown coefficients, 4N equations representing a relation among the unknown coefficients are necessary. Therefore, several conditions are applied to the equations. A first condition is that the spline passes all the N data points. Since coordinate values at both ends of the respective sections are determined from the condition, 2N equations can be obtained. The next condition is that linear derived functions at boundary points of the respective sections are continuous. Since N−1 boundary points are present, N−1 equations can be obtained from the condition. The next condition is that quadratic derived functions at the boundary points of the respective sections are continuous. N−1 equations can also be obtained from the condition.

Therefore, the conditions are represented by 4N−2 equations. However, since the 4N equations are necessary to calculate the unknown coefficients, there is still a lack of two equations. To supplement this lack of equations, various conditions are conceivable. In a normal case, a condition that values of quadratic derived functions at both ends (x=x₀, x_{N-1}) of a spline section are zero is used. In other words, a condition s₀″(x₀)−s_{N-1}″(x_{N-1})=0 is used. A spline that satisfies the condition is referred to as natural spline. In this embodiment, the natural spline is adopted. However, a type of the spline is not specifically limited. For example, it is also possible to adopt a spline in which a value other than zero is designated as values of linear derived functions at both the ends in the spline section.

Next, simultaneous equations that satisfy the condition of the natural spline are calculated. A value of a quadratic function of a divided interpolation formula sⱼ(x) in x=xⱼ is represented as uⱼ. uⱼ is represented by the following Formula (5):

uⱼ=sⱼ″(xⱼ) (j=0, 1, 2, . . . , N−1) (5)

When uⱼ=sⱼ₋₁″(xⱼ)=sⱼ″(xⱼ), the condition of the quadratic derived function is satisfied. The following Formulas (6) and (7) are derived from the calculation of the quadratic derived function of the divided interpolation formula sⱼ(x):

uⱼ=sⱼ″(x)=2bⱼ (j=0, 1, 2, . . . , N−1) (6)

bⱼ=uⱼ/2 (7)

Further, when x=xⱼ is substituted in the quadratic derived function of the divided interpolation formula sⱼ(x), the following Formula (8) is derived:

uⱼ₊₁=sⱼ″(xⱼ₊₁)=6aⱼ(xⱼ₊₁−xⱼ)+2bⱼ (j=0, 1, 2, . . . , N−1) (8)

When aⱼ is calculated from Formula (8), the following Formula (9) is derived:

$$\begin{matrix}{a}_{j} = \frac{{u}_{j + 1} - 2 {b}_{j}}{6 ( {x}_{j + 1} - {x}_{j} )} \\ = \frac{{u}_{j + 1} - {u}_{j}}{6 ( {x}_{j + 1} - {x}_{j} )} ( j = 0 , 1 , 2 , … , N - 1 )\end{matrix} \qquad ( 9 )$$

The first condition that the spline passes all the data points is examined below. First, since the spline passes data points at the left ends of the respective sections, the following Formula (10) is derived:

dⱼ=yⱼ (10)

Next, since the spline passes data points at right ends of the respective sections, the following Formula (11) is derived:

aⱼ(xⱼ₊₁−xⱼ)³+bⱼ(xⱼ₊₁−xⱼ)²+cⱼ(xⱼ₊₁−xⱼ)+dⱼ=yⱼ₊₁ (11)

When Formulas (4), (6), and (7) are used, the following formula (12) is derived:

$$\begin{matrix}{c}_{j} = \frac{1}{{x}_{j + 1} - {x}_{j }} [ \begin{matrix}{y}_{j + 1} - {{a}_{j} ( {x}_{j + 1} - {x}_{j} )}^{3} - \\ {{b}_{j} ( {x}_{j + 1} - {x}_{j} )}^{2} - {d}_{j}\end{matrix} ] \\ = \frac{1}{{x}_{j + 1} - {x}_{j }} [ \begin{matrix}{y}_{j + 1} - ( \frac{{u}_{j + 1} - {u}_{j}}{6 ( {x}_{j + 1} - {x}_{j} )} ) {( {x}_{j + 1} - {x}_{j} )}^{3} - \\ \frac{{u}_{j}}{2} {( {x}_{j + 1} - {x}_{j} )}^{2} - {y}_{j}\end{matrix} ] \\ = \frac{{y}_{j + 1} - {y}_{j }}{{x}_{j + 1} - {x}_{j }} - \frac{1}{6} ( {x}_{j + 1} - {x}_{j } ) ( 2 {u}_{j} + {u}_{j + 1} )\end{matrix} \qquad ( 12 )$$

Consequently, xⱼ, yⱼ, and uⱼ can be described by using the unknown coefficients aⱼ, bⱼ, cⱼ, and dⱼ. Since xⱼ and yⱼ are unknown values, all unknown coefficients necessary for interpolation are calculated if uⱼ is calculated. To calculate uⱼ, a condition that unused linear derived functions are the same at boundary points of sections only has to be used. Specifically, the following Formula (13) is used:

sⱼ′(xⱼ₊₁)=sⱼ₊₁′(xⱼ₊₁) (j=0, 1, 2, . . . , N−2) (13)

The following Formula (14) is derived from Formulas (13) and (4).

3aⱼ(xⱼ₊₁−xⱼ)²+2bⱼ(xⱼ₊₁−xⱼ)+cⱼ=cⱼ₊₁ (14)

Simultaneous equations of uⱼ are obtained by describing aⱼ, bⱼ, cⱼ, and dⱼ in Formula (14) with xⱼ, yⱼ, and uⱼ. Consequently, the following Formula (15) is finally derived.

$$( {x}_{j + 1} - {x}_{j } ) {u}_{j} + 2 ( {x}_{j + 2} - {x}_{j} ) {u}_{j} + ( {x}_{j + 2} - {x}_{j + 1 } ) {u}_{j} + 2 = 6 [ \frac{{y}_{j + 2} - {y}_{j + 1 }}{{x}_{j + 2} - {x}_{j + 1 }} - \frac{{y}_{j + 1} - {y}_{j }}{{x}_{j + 1} - {x}_{j }} ] ( j = 0 , 1 , 2 , … , N - 2 ) \qquad ( 15 )$$

The number of equations in Formula (15) is N−1. Although the number of uⱼ's is N+1, since u₀=u_{N}= , the number of unknown uⱼ's is N−1. All uⱼ's can be determined by solving Formula (15). When all uⱼ's are determined, the unknown coefficients aⱼ, bⱼ, cⱼ, and dⱼ can be calculated. Simultaneous linear equations in which u₀=u_{N}=0 is substituted is described by the following Formula (16). hⱼ and vⱼ are described by the following Formulas (17) and (18):

$$\begin{matrix}( \begin{matrix}2 ( \begin{matrix}{h}_{0} + \\ {h}_{1}\end{matrix} ) & {h}_{1} & & & & 0 & \\ {h}_{1} & 2 ( \begin{matrix}{h}_{1} + \\ {h}_{2}\end{matrix} ) & {h}_{2} & & & & \\ & {h}_{2} & 2 ( \begin{matrix}{h}_{2} + \\ {h}_{3}\end{matrix} ) & {h}_{3} & & & \\ & & & ⋱ & & & \\ & & & {h}_{j - 1} & 2 ( \begin{matrix}{h}_{j - 1} + \\ {h}_{j}\end{matrix} ) & {h}_{j} & \\ & & & & & ⋱ & \\ & 0 & & & & {h}_{N - 2} & 2 ( \begin{matrix}{h}_{N - 2} + \\ {h}_{N - 1}\end{matrix} )\end{matrix} ) \\ ( \begin{matrix}{u}_{1} \\ {u}_{2} \\ {u}_{3} \\ ⋮ \\ {u}_{j} \\ ⋮ \\ {u}_{N - 1}\end{matrix} ) = ( \begin{matrix}{v}_{1} \\ {v}_{2} \\ {v}_{3} \\ ⋮ \\ {v}_{j} \\ ⋮ \\ {v}_{N - 1}\end{matrix} ) & ( 16 ) \\ {h}_{j} = {x}_{j + 1} - {x}_{j} ( j = 0 , 1 , 2 , … , N - 1 ) & ( 17 ) \\ {v}_{j} = 6 [ \frac{{y}_{j + 1} - {y}_{j}}{{h}_{j}} - \frac{{y}_{j} - {y}_{j - 1 }}{{h}_{j - 1}} ] ( j = 0 , 1 , 2 , … , N - 1 ) & ( 18 )\end{matrix}$$

In this way, all the 4N unknown coefficients are calculated and spline interpolation can be performed. In general, in the case of an n−1th order spline interpolation method employing an n−1th order polynomial, n data points are necessary. When data points are insufficient, a data point before a start point of a clip portion as a spline section or a data point after an end point of the clip portion only has to be used as a data point for the spline interpolation. Consequently, it is possible to solve the insufficiency of the data points.

### Second Embodiment

A second embodiment of the present invention is explained below.

### [A Configuration Example of a Sound Reproducing Device According to the Second Embodiment]

FIG. 21 is a block diagram of a configuration example of a sound reproducing device as a signal processing device according to the second embodiment.

A sound reproducing device 141 of the example shown in FIG. 21 is configured as, for example, a sound reproduction section of a video camera. The sound reproducing device 141 reads out a sound signal from a recording medium, for example, a recording medium 151 inserted therein, reproduces the sound signal, and applies predetermined processing to the sound signal. The sound reproducing device 141 outputs a sound signal obtained as a result of the processing to the outside as sound via a speaker 156.

The sound reproducing device 141 of the example shown in FIG. 21 uses a waveform processing circuit same as the waveform processing circuit 43 in the sound recording device 31 of the example shown in FIG. 13. Therefore, in the following explanation, the reference numerals and signs of the waveform processing circuit 43 is used. The sound reproducing device 141 includes the waveform processing circuit 43, a reproducing circuit 152, a decoder 153, a D/A converter 154, an amplifier circuit 155, and a speaker 156.

For example, the reproducing circuit 152 reads out a sound signal from the recording medium 151, reproduces the sound signal, and supplies the sound signal to the decoder 153. The decoder 153 applies demodulation processing to the sound signal and then supplies the sound signal to the waveform processing circuit 43. The waveform processing circuit 43 applies waveform processing such as amplitude compression processing to a digital sound signal and then supplies the digital sound signal to the D/A converter 154. The D/A converter 154 applies D/A conversion to the digital sound signal and supplies an analog sound signal to the amplifier circuit 155. The amplifier circuit 155 applies power amplification processing to the analog sound signal and supplies the analog sound signal to the speaker 156 as an electric signal. The speaker 156 outputs the electric signal to the outside as sound.

The waveform processing circuit 43 of the sound reproducing device 141 can limit amplitude according to the abilities of the D/A converter 154 and the amplifier circuit 155 while keeping an original waveform as much as possible. Therefore, the sound reproducing device 141 can reproduce sound more faithful to original sound in a range of abilities of circuits in the inside thereof.

As the first threshold, for example, an arbitrary value can be adopted depending on a signal processing circuit at a post-stage such as the D/A converter 154 or the amplifier circuit 155. Specifically, for example, a value corresponding to a dynamic range of the signal processing at the post-stage can be adopted as the first threshold. The waveform processing circuit 43 can execute processing such as the amplitude compression processing at high speed, accumulate a sound signal in the memory 101 or the like in the inside, and supply the sound signal to the D/A converter 154. Consequently, it is possible to prevent a phenomenon in which sound output from the speaker 156 breaks off.

### Third Embodiment

A third embodiment of the present invention is explained below.

### [A Configuration Example of a Sound Recording Device According to the Third Embodiment]

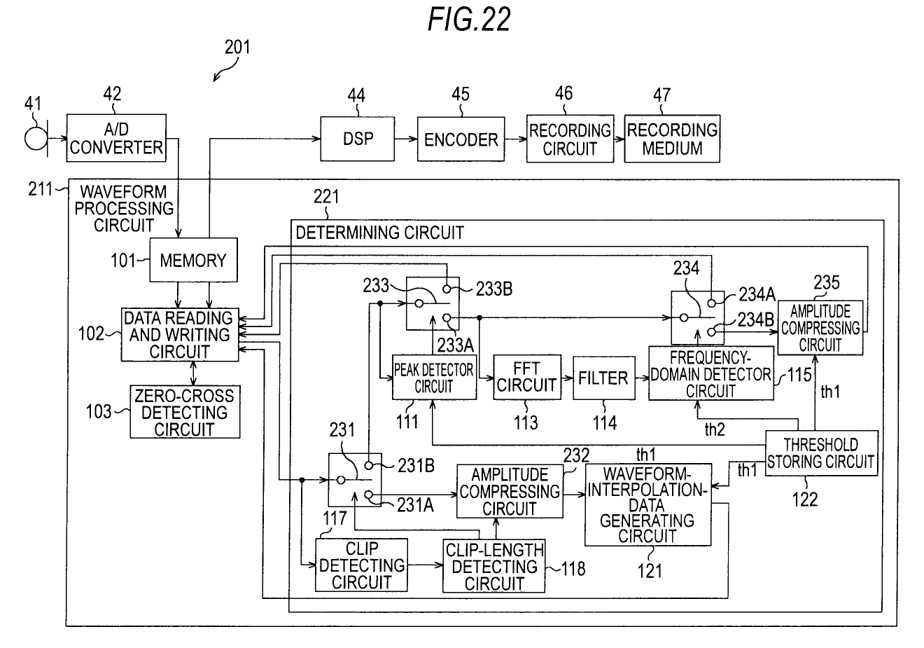

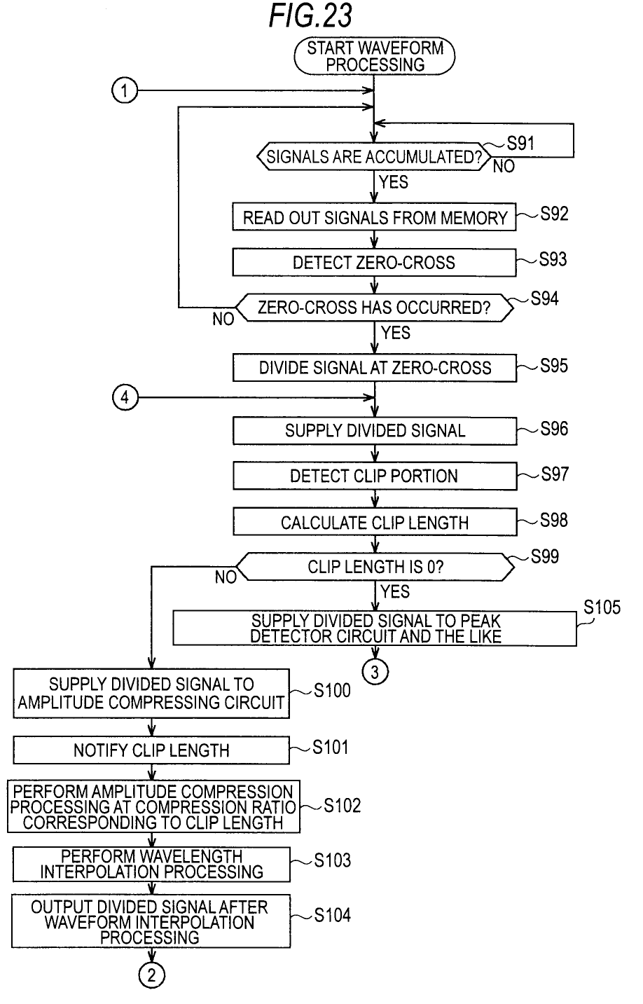

FIG. 22 is a block diagram of a configuration example of a sound recording device as a signal processing device according to the third embodiment.

A sound recording device 201 of the example shown in FIG. 22 includes a waveform processing circuit 211 of the example shown in FIG. 22 instead of the waveform processing circuit 43 of the sound recording device 31 of the example shown in FIG. 13. The waveform processing circuit 211 of the example shown in FIG. 22 includes a determining circuit 221 instead of the determining circuit 104 of the sound recording device 31 of the example shown in FIG. 13. In the determining circuit 221 of the example shown in FIG. 22, the switch 112, the switch 116, the amplitude compressing circuit 119, and the switch 120 of the example shown in FIG. 13 are deleted. A switch 231, an amplitude compressing circuit 232, a switch 233, a switch 234, and an amplitude compressing circuit 235 are added anew.

### [A Processing Example of the Waveform Processing Circuit]

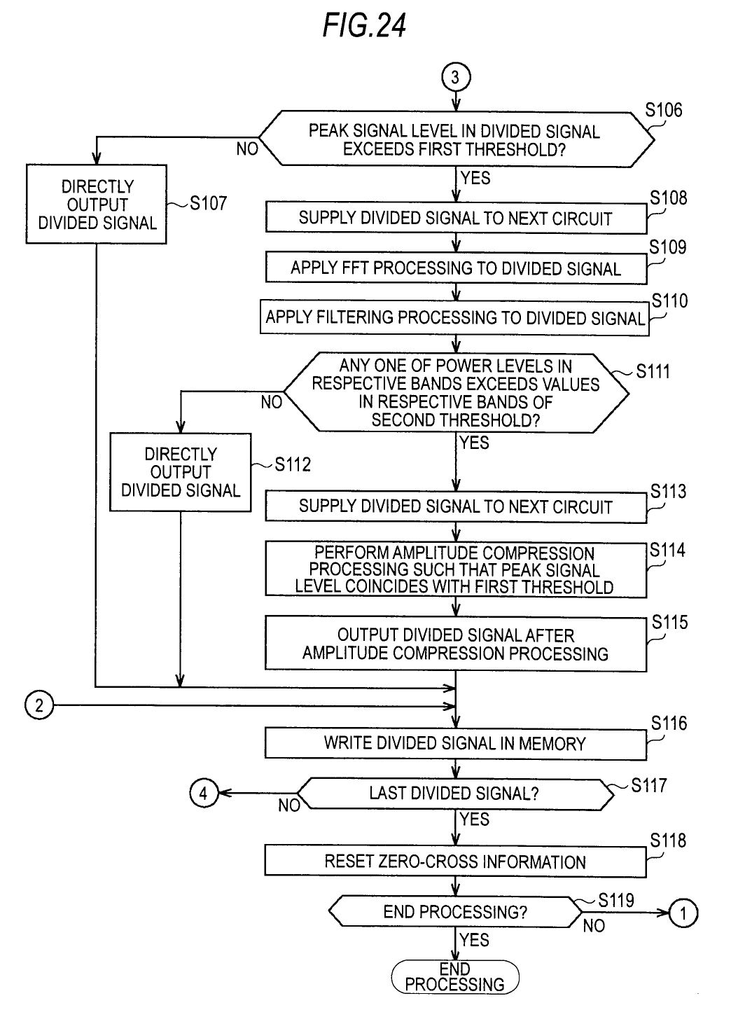

A processing example of the waveform processing circuit 211 is explained below with reference to flowcharts shown in FIGS. 23 and 24. The processing by the waveform processing circuit 211 is hereinafter referred to as waveform processing.

Processing in steps S91 to S95 of the example shown in FIG. 23 is the same as the processing in steps S11 to S15 of the example shown in FIG. 15. Therefore, explanation of the processing is omitted. In the following explanation, explanation of processing same as the processing in the first embodiment is omitted as appropriate. In step S96, the data reading and writing circuit 102 reads out a predetermined divided signal from the memory 101 and supplies the divided signal to the clip detecting circuit 117 and the switch 231 of the determining circuit 221. Processing in steps S97 and S98 of the example shown in FIG. 23 is the same as the processing in steps S25 and S26 of the example shown in FIG. 16. In step S99, the clip-length detecting circuit 118 determines whether clip length of the divided signal is zero.

When the clip-length detecting circuit 118 determines in step S99 that the clip length of the divided signal is not zero (NO in step S99), the processing proceeds to step S100. The clip-length detecting circuit 118 notifies the amplitude compressing circuit 232 of the (non-zero) clip length of the divided signal. Thereafter, the processing proceeds to step S102.

On the other hand, when the clip-length detecting circuit 118 determines in step S99 that the clip length of the divided signal is zero, the processing proceeds to step S105. Processing in steps S102 to S104 of the example shown in FIG. 23 is the same as the processing in steps S29 to S31 of the example shown in FIG. 16. In step S105, the clip-length detecting circuit 118 changes over the switch 233 to a terminal 233B. Processing in step S106 of the example shown in FIG. 23 is the same as the processing in step S17 of the example shown in FIG. 15. In step S107, the peak detector circuit 111 changes over the switch 233 to the terminal 233B. Thereafter, the processing proceeds to step S116.

When the data reading and writing circuit 102 determines in step S106 that the peak signal level in the divided signal exceeds the first threshold th1 (YES in step S106), the processing proceeds to step S108. The peak detector circuit 111 changes over the switch 233 to a terminal 233A. Processing in steps S109 to S111 of the example shown in FIG. 23 is the same as the processing in steps S20 to S22 of the example shown in FIGS. 15 and 16. In step S112, the frequency-domain detector circuit 115 changes over the switch 234 to a terminal 234A. Thereafter, the processing proceeds to step S116.

When the frequency-domain detector circuit 115 determines in step S111 that any one of the power levels in the respective bands of the frequency domain signal exceeds the values in the respective bands of the second threshold th2 (YES in step S111), the processing proceeds to step S113. In step S113, the frequency-domain detector circuit 115 changes over the switch 234 to a terminal 234B. In step S114, the amplitude compressing circuit 235 applies amplitude compression to the divided signal such that the peak signal level of the divided signal coincides with the first threshold th1. In step S115, the amplitude compressing circuit 235 outputs the divided signal after the amplitude compression processing to the data reading and writing circuit 102. Thereafter, the processing proceeds to step S116. Processing in steps S116 to S119 of the example shown in FIG. 23 is the same as the processing in steps S36 to S39 of the example shown in FIG. 16.

As explained above, the waveform processing circuit 211 of the example shown in FIG. 22 can perform waveform processing same as the waveform processing by the waveform processing circuit 43 of the example shown in FIG. 14, although a procedure of the processing is different.

### [Application of the Present Invention to a Computer Program]

The series of processing explained above can be executed by hardware or can be executed by software. When the series of processing is executed by the software, a computer program configuring the software is installed from a program recording medium. The computer program is installed in, for example, a computer incorporated in dedicated hardware. The computer program is installed in, for example, a general-purpose personal computer that can execute various functions by installing various computer programs therein.

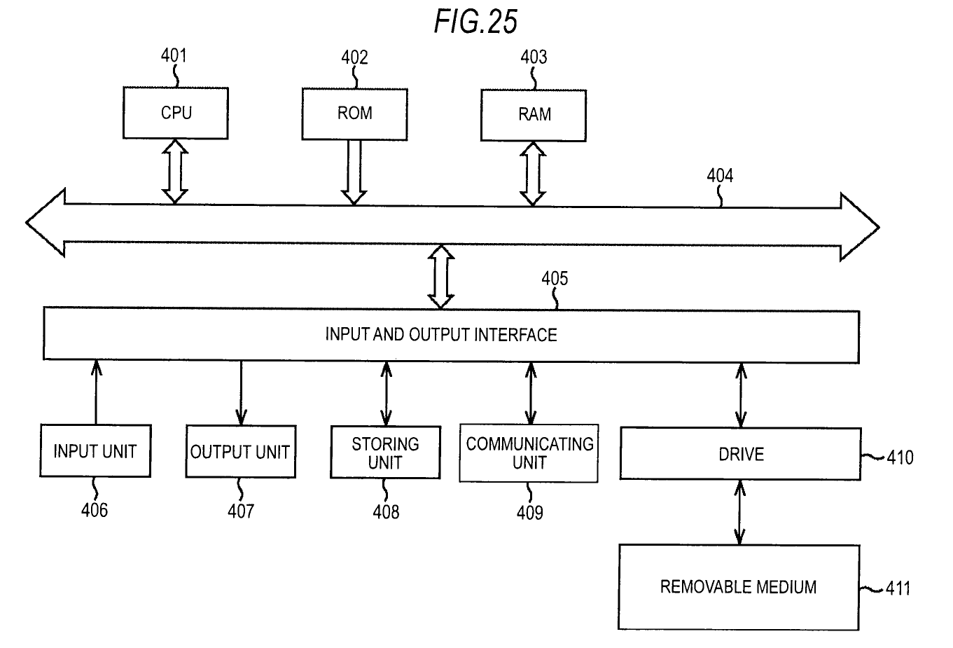

FIG. 25 is a block diagram of a configuration example of the hardware of the computer that executes the series of processing according to the computer program.

In the computer, a CPU 401, a ROM (Read Only Memory) 402, and a RAM (Random Access Memory) 403 are connected to one another by a bus 404. An input and output interface 405 is further connected to the bus 404. An input unit 406 including a keyboard, a mouse, and a microphone, an output unit 407 including a display and a speaker, and a storing unit 408 including a hard disk and a nonvolatile memory are connected to the input and output interface 405. A communicating unit 409 including a network interface and a drive 410 that drives a removable medium 411 such as a magnetic disk, an optical disk, a magneto-optical disk, or a semiconductor memory are further connected to the input and output interface 405.

In the computer configured as explained above, the CPU 401 loads, for example, a computer program stored in the storing unit 408 to the RAM 403 via the input and output interface 405 and the bus 404 and executes the computer program, whereby the series of processing is performed. The computer program executed by the computer (the CPU 401) is provided while being recorded in, for example, the removable medium 411 that is a magnetic disk (including a flexible disk). The computer program is provided while being recorded in the removable medium 411 that is a package medium. As the package medium, an optical disk (a CD-ROM (Compact Disc-Read Only Memory), a DVD (Digital Versatile Disc), etc.), a magneto-optical disk, a semiconductor memory, or the like is used. Alternatively, the computer program is provided via a wired or wireless transmission medium such as a local area network, the Internet, or a digital satellite broadcast. The computer program can be installed in the storing unit 408 via the input and output interface 405 by inserting the removable medium 411 in the drive 410. The computer program can be received by the communicating unit 409 via the wired or wireless transmission medium and installed in the storing unit 408. Besides, the computer program can be installed in the ROM 402 and the storing unit 408 in advance.

The computer program executed by the computer may be a computer program with which processing is performed in time series according to the procedure explained in this specification or a computer program with which processing is performed in parallel or at necessary timing such as the time when the computer program is invoked.

Embodiments of the present invention are not limited to the embodiments explained above and various modifications of the embodiments are possible without departing from the spirit of the present invention.

The present application contains subject matter related to that disclosed in Japanese Priority Patent Application JP 2009-090585 filed in the Japan Patent Office on Apr. 3, 2009, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A signal processing device comprising:
a frequency conversion processing unit that sets, as a processing target signal, a section in which a peak signal level exceeds a first threshold in an input sound signal and applies frequency conversion processing to the processing target signal to acquire power levels in respective plural bands; and
an amplitude compressing unit that executes, when a power level exceeding a second threshold is present among the power levels in the respective plural bands acquired by the frequency conversion processing unit, amplitude compression processing for compressing a signal level of the processing target signal at a compression ratio at which the peak signal level of the processing target signal falls within the first threshold and, otherwise, prohibits the execution of the amplitude compression processing.

2. A signal processing device according to claim 1, further comprising:
a clip detecting unit that detects, out of the input sound signal, a clip portion, a waveform of which is distorted by a dynamic range of a circuit; and
a waveform interpolating unit that interpolates, in the processing target signal subjected to the amplitude compression processing by the amplitude compressing unit, a waveform of a sound signal in which the clip portion is detected by the clip detecting unit and changes the waveform to a waveform in which the peak signal level is the first threshold.

3. A signal processing device according to claim 2, further comprising a zero-cross detecting unit that detects, concerning the input sound signal, a position of a point where a signal level crosses a bias as a zero-cross, wherein
a processing unit of the clip detecting unit and a unit of the processing target signal are a signal between a pair of the zero-crosses detected by the zero-cross detecting unit.

4. A signal processing device according to claim 2, wherein the amplitude compressing unit applies, when the clip portion detected by the clip detecting unit is included in the processing target signal, the amplitude compression processing to the processing target signal at the compression ratio corresponding to time length of the clip portion.

5. A signal processing device according to claim 2, wherein the amplitude compressing unit applies, when the clip portion detected by the clip detecting unit is not included in the processing target signal, the amplitude compression processing to the processing target signal at the compression ratio at which the peak signal level is the first threshold.

6. A signal processing device according to claim 1, wherein the second threshold has an independent value for each of the plural bands.

7. A signal processing device according to claim 1, further comprising a filter unit that applies filtering adjusted to a human audibility characteristic to the power levels in the respective plural bands acquired by the frequency conversion processing unit, wherein
the amplitude compressing unit distinguishes the execution and the prohibition of the amplitude compression processing using the power levels in the respective plural bands subjected to the filtering by the filtering unit.

8. A signal processing method comprising the steps of:
a signal processing device setting, as a processing target signal, a section in which a peak signal level exceeds a first threshold in an input sound signal and applying frequency conversion processing to the processing target signal to acquire power levels in respective plural bands; and
the signal processing device executing, when a power level exceeding a second threshold is present among the acquired power levels in the respective plural bands, amplitude compression processing for compressing a signal level of the processing target signal at a compression ratio at which the peak signal level of the processing target signal falls within the first threshold and, otherwise, prohibiting the execution of the amplitude compression processing.

9. A computer program for causing a computer to execute control processing including the steps of:
setting, as a processing target signal, a section in which a peak signal level exceeds a first threshold in an input sound signal and applying frequency conversion processing to the processing target signal to acquire power levels in respective plural bands; and
executing, when a power level exceeding a second threshold is present among the acquired power levels in the respective plural bands, amplitude compression processing for compressing a signal level of the processing target signal at a compression ratio at which the peak signal level of the processing target signal falls within the first threshold and, otherwise, prohibiting the execution of the amplitude compression processing.
